(19) United States
(12) Patent Application Publication
(10) Pub. No.: US 2025/0380529 A1
(43) Pub. Date: Dec. 11, 2025

(54) IMAGING ELEMENT AND IMAGE SENSOR

(71) Applicant: TIANMA JAPAN, LTD., Kawasaki (JP)

(72) Inventors: Takayuki ISHINO, Kawasaki (JP); Hiroyuki SEKINE, Kawasaki (JP); Koichi IWASA, Kawasaki (JP)

(21) Appl. No.: 19/226,819

(22) Filed: Jun. 3, 2025

(30) Foreign Application Priority Data
Jun. 7, 2024 (JP) 2024-093094
Feb. 17, 2025 (JP) 2025-023635

(51) Int. Cl. H10F 39/00; H10F 39/12; H10F 77/169

(52) U.S. Cl. CPC H10F 39/811; H10F 77/169; H10F 39/195

(57) ABSTRACT

An imaging element disposed on a substrate includes a photodetector, a thin-film transistor disposed between the photodetector and the substrate, and a signal line configured to transmit a signal from the photodetector via the thin-film transistor. At least a part of the signal line includes a first signal line layer and a second signal line layer directly laid one above the other. At least a part of the thin-film transistor is covered with the photodetector in a planar view. The second signal line layer extends outside the photodetector in a planar view. The first signal line layer is included in the same metal layer pattern as a drain electrode of the thin-film transistor and is continued to the drain electrode.

### CROSS-REFERENCE TO RELATED APPLICATIONS

This non-provisional application claims priority under 35 U.S.C. § 119 (a) on Patent Application No. 2024-093094 filed in Japan on Jun. 7, 2024 and Patent Application No. 2025-23635 filed in Japan on Feb. 17, 2025, the entire contents of which are hereby incorporated by reference.

### BACKGROUND

This disclosure relates to the structure of an imaging element including a photodetector and a thin-film transistor and an imaging sensor including the imaging element.

The technology for non-destructively inspecting the inside of a specimen with an image of X-rays transmitted through the specimen is crucial for the fields of medical and industrial non-destructive testing. Especially, digital radiography (DR) that directly captures the image of transmitted X-rays as electronic data has become widely employed because of availability of quick image reading and image interpretation assistance through image processing. The DR uses a device called flat panel detector (FPD).

The FPDs used for X-ray image sensors are generally categorized as a direct conversion type and an indirect conversion type. The indirect conversion type of FPDs as X-ray detection panels include a phosphor (scintillator) that converts X-rays into light (such as visible light or ultraviolet light) and a photoelectric conversion element array that converts the light into an electric signal. An FPD includes an imaging element board on which imaging elements are arrayed. Each imaging element includes a photodetector (photodiode) that converts X-rays or light into an electric signal and a switching thin-film transistor for taking out the electric signal.

The common pixel pitch attained by imaging elements including a thin-film transistor has been 120 to 200 um so far. In recent years, however, products having a pixel pitch of 100 nm or even smaller 70 to 80 nm have been brought to the market; X-ray image sensors are attaining higher resolution. Moreover, there is a demand for attaining a pixel pitch of approximately 50 um with imaging elements including a thin-film transistor, although such a pixel pitch has been only realized by CMOS X-ray image sensors.

### SUMMARY

An aspect of this disclosure is an imaging element disposed on a substrate including a photodetector, a thin-film transistor disposed between the photodetector and the substrate, and a signal line configured to transmit a signal from the photodetector via the thin-film transistor. At least a part of the signal line includes a first signal line layer and a second signal line layer directly laid one above the other. At least a part of the thin-film transistor is covered with the photodetector in a planar view. The second signal line layer extends outside the photodetector in a planar view. The first signal line layer is included in the same metal layer pattern as a drain electrode of the thin-film transistor and is continued to the drain electrode.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration example of an image sensor in an embodiment of this specification.

FIG. 2 is a circuit diagram of an equivalent circuit of one pixel.

FIG. 3A is a plan diagram schematically illustrating the structure of a pixel including a photodiode, a thin-film transistor, a part of a gate line and a part of a signal line.

FIG. 3B is a cross-sectional diagram along the section line IIIB-IIIB′ in FIG. 3A.

FIG. 4A is a cross-sectional diagram schematically illustrating a structural example of a thin-film transistor and a signal line.

FIG. 4B is a cross-sectional diagram schematically illustrating another structural example of a thin-film transistor and a signal line.

FIG. 4C is a cross-sectional diagram schematically illustrating still another structural example of a thin-film transistor and a signal line.

FIG. 5A is a cross-sectional diagram schematically illustrating still another structural example of a thin-film transistor and a signal line.

FIG. 5B is a cross-sectional diagram schematically illustrating still another structural example of a thin-film transistor and a signal line.

FIG. 5C is a cross-sectional diagram schematically illustrating still another structural example of a thin-film transistor and a signal line.

FIG. 6 is a flowchart for explaining a manufacturing method applicable to the structural examples in FIGS. 5A, 5B, and 5C.

FIG. 7 is a flowchart for explaining a manufacturing method applicable to the structural examples in FIGS. 3B, 4A, and 4B.

FIG. 8 is a flowchart for explaining a manufacturing method applicable to the structural example in FIG. 4C.

FIG. 9A is a plan diagram schematically illustrating another structural example of an imaging element.

FIG. 9B schematically illustrates the cross-sectional structure along the section line IXB-IXB′ in FIG. 9A.

FIG. 9C is a plan diagram schematically illustrating a pixel structure of a related art.

FIG. 10A is a plan diagram schematically illustrating still another structural example of an imaging element.

FIG. 10B schematically illustrates the cross-sectional structure along the section line XB-XB′ in FIG. 10A.

FIG. 11A illustrates the structure of a pixel of an imaging element in an embodiment of this specification.

FIG. 11B schematically illustrates the cross-sectional structure along the section line XIB-XIB′ in the plan diagram of FIG. 11A

FIG. 11C schematically illustrates the cross-sectional structure along the section line XIC-XIC′ in the plan diagram of FIG. 11A.

FIG. 12A is a cross-sectional diagram schematically illustrating a structural example of a thin-film transistor and a signal line.

FIG. 12B is a cross-sectional diagram schematically illustrating another structural example of a thin-film transistor and a signal line.

FIG. 12C is a cross-sectional diagram schematically illustrating still another structural example of a thin-film transistor and a signal line.

FIG. 13A is a cross-sectional diagram schematically illustrating still another structural example of a thin-film transistor and a signal line.

FIG. 13B is a cross-sectional diagram schematically illustrating still another structural example of a thin-film transistor and a signal line.

FIG. 13C is a cross-sectional diagram schematically illustrating still another structural example of a thin-film transistor and a signal line.

FIG. 14A illustrates the structure of a pixel of an imaging element in an embodiment of this specification.

FIG. 14B schematically illustrates the cross-sectional structure along the section line XIVB-XIVB′ in the plan diagram of FIG. 14A.

FIG. 15A illustrates a step in a method to manufacture the structural example in FIGS. 14A and 14B.

FIG. 15B illustrates a step in the method to manufacture the structural example in FIGS. 14A and 14B.

FIG. 15C illustrates a step in the method to manufacture the structural example in FIGS. 14A and 14B.

FIG. 16A illustrates the structure of a pixel of an imaging element in an embodiment of this specification.

FIG. 16B schematically illustrates the cross-sectional structure along the section line XVIB-XVIB′ in the plan diagram of FIG. 16A.

FIG. 16C schematically illustrates the cross-sectional structure along the section line XVIC-XVIC′ in the plan diagram of FIG. 16A.

FIG. 17A illustrates a step in a method to manufacture the structural example in FIGS. 16A, 16B, and 16C.

FIG. 17B illustrates a step in the method to manufacture the structural example in FIGS. 16A, 16B, and 16C.

FIG. 17C illustrates a step in the method to manufacture the structural example in FIGS. 16A, 16B, and 16C.

FIG. 18 is a cross-sectional diagram schematically illustrating a structural example of a thin-film transistor.

FIG. 19 is a cross-sectional diagram schematically illustrating a structural example of a thin-film transistor and a photodiode.

FIG. 20 provides experimental results on elements provided with a different height of step-like part in a layer under a photodiode having a thickness of 1 um and an element not provided with such a step-like part. The heights of the step-like parts were 0.2 um, 0.7 um, and 1.2 um and the experiment measured the leak current while varying the bias current applied to the photodiode.

FIG. 21 provides experimental results on elements having a different thickness of inorganic interlayer insulating film between a photodiode having a thickness of 1 um and a layer including a step-like part having a height of 1 um under the photodiode and an element provided with neither a step-like part nor an inorganic interlayer insulating film. The thicknesses of the inorganic interlayer insulating films were 0.2 um, 0.7 um, and 1.2 um and the experiment measured the leak current while varying the bias current applied to the photodiode.

### EMBODIMENTS

Hereinafter, imaging elements in embodiments of this specification that are applicable to radiation image sensor will be described in detail with reference to the drawings. The imaging element of this disclosure is applicable to radiation image sensors in the fields of medical and industrial non-destructive testing, for example. The light to be detected by the imaging element board is electromagnetic rays having an arbitrary frequency, which can be infrared rays, visible light, or X-rays. The configuration of the imaging element of this disclosure are applicable to devices different from radiation image sensors.

The elements in the drawings are changed in size or scale as appropriate to be well recognized in the drawings. The hatches in the drawings are to distinguish the elements and are not necessarily to represent cross-sections.

From the viewpoint of raising the pixel density, the sizes of thin-film transistors (TFTs), lines, and contact holes have already been minimized; more downsizing is difficult for the current technology. Accordingly, unless the elements such as thin-film transistors, lines, contact holes, and photodetectors overlap each other in a planar view, the major means to raise the pixel density is decreasing only the light receiving area of each photodetector. This means significantly lowers the fill factor (the proportion of light receiving area).

A thin-film transistor occupies a relatively large area and therefore, a pixel structure such that the thin-film transistor overlaps the photodetector has a certain effect to increase the light receiving area and the fill factor. Even with the pixel structure in which the thin-film transistor overlaps the photodetector, however, more raising the pixel density increases the proportion of the area occupied by lines and contact holes and significantly lowers the fill factor. As a result, the sensitivity lowers to degrade the performance of the image sensor.

In the case of forming the signal line, the source electrode, and the drain electrode in the same metal layer and disposing the photodetector to overlap the thin-film transistor while keeping the resistance of the signal line low, step-like parts having a large height difference are generated because of the thick signal line, source electrode, and drain electrode. There is an experimental result as follows: when a height difference of approximately 1 um, which is almost equal to the thickness of the signal line, is provided under the photodetector, the leak current of the photodiode increases by approximately five times compared to when no height difference is provided. The increase in leak current of a photodiode reduces the dynamic range and increases the noise, degrading the performance of the image sensor.

The signal line in an aspect of this disclosure includes a first signal line layer and a second signal line layer directly laid one above the other in at least a part of it. In a planar view, a photodetector such as a photodiode covers at least a part of a thin-film transistor and the second signal line layer extends outside the photodetector. The first signal line layer is included in the same metal layer pattern as the drain electrode of the thin-film transistor and it is continued to the drain electrode. This structure enables increases in light receiving area with a small height difference under the photodetector while suppressing increase in resistance of the signal line.

### Embodiment 1

### Overall Configuration of Image Sensor

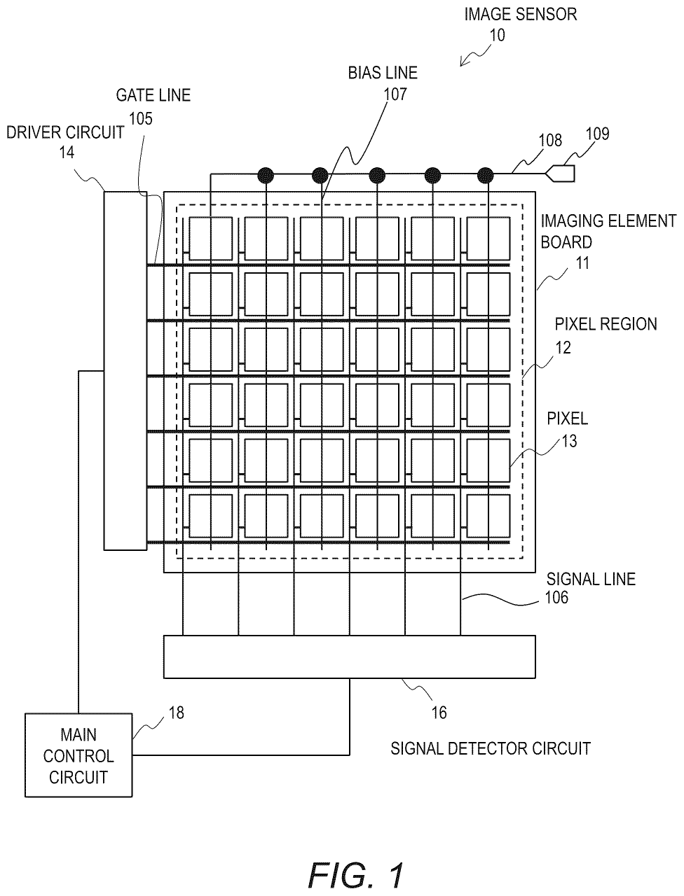

FIG. 1 is a block diagram illustrating a configuration example of an image sensor in an embodiment of this specification. The image sensor 10 includes an imaging element board 11 and control circuits. The control circuits include a driver circuit 14, a signal detector circuit 16, and a main control circuit 18.

The imaging element board 11 includes an insulating substrate (such as a glass substrate) and a pixel region 12 on the insulating substrate. In the pixel region 12, pixels 13 are arrayed horizontally and vertically like a matrix. A pixel 13 is an example of an imaging element fabricated on the substrate and includes a photodiode of a photodetector. The layout of the pixels 13 is not limited to the matrix layout illustrated in FIG. 1. The pixel region 12 can include scintillator that emits fluorescence in response to radial rays to be detected.

The pixels 13 are disposed at intersections between a plurality of signal lines 106 and a plurality of gate lines (scanning lines) 105. In FIG. 1, the signal lines 106 are disposed to extend vertically and be horizontally distant from one another. The gate lines 105 are disposed to extend horizontally and be vertically distant from one another. Each pixel 13 is connected to a bias line 107. In FIG. 1, bias lines are disposed to extend vertically and be horizontally distant from one another. In FIG. 1, only one of the pixels, one of the signal lines, one of the gate lines, and one of the bias lines are provided with reference signs 13, 106, 105, and 107, respectively.

Each signal line 106 is connected to a different pixel column. Each gate line 105 is connected to a different pixel row. The signal line 106 is connected to the signal detector circuit 16 and the gate line 105 is connected to the driver circuit 14. The bias lines 107 are connected to a common bias line 108. A pad 109 of the common bias line 108 is supplied with a bias potential. The driver circuit 14 drives the gate lines 105 of the pixels 13 to detect light with the pixels 13. The signal detector circuit 16 detects signals from individual signal lines. The main control circuit 18 controls the driver circuit 14 and the signal detector circuit 16.

### Equivalent Circuit of Pixel

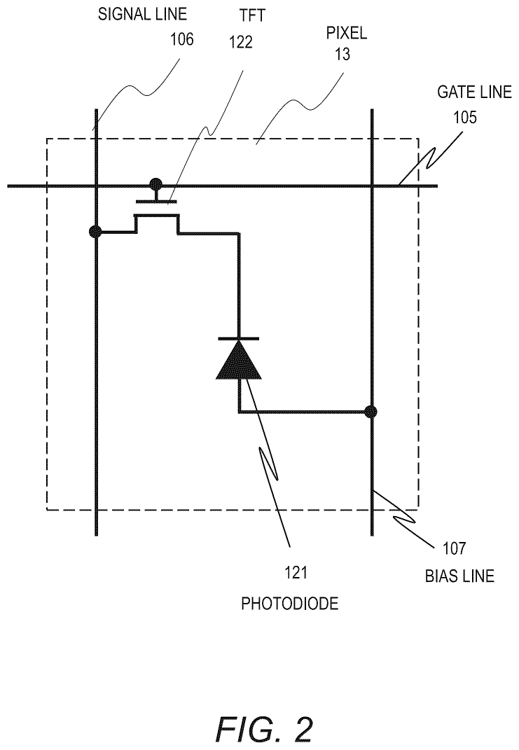

FIG. 2 is a circuit diagram of an equivalent circuit of one pixel 13. A pixel 13 includes a photodiode 121 of a photoelectric conversion element and a thin-film transistor (TFT) 122 of a switching element. The gate terminal of the thin-film transistor 122 is connected to a gate line 105; one of the source/drain terminals is connected to a signal line 106; and the other source/drain terminal is connected to the cathode terminal of the photodiode 121. In the example of FIG. 2, the anode terminal of the photodiode 121 is connected to a bias line 107.

The thin-film transistor 122 can be an amorphous silicon (a-Si) thin-film transistor, a polysilicon thin-film transistor, or an oxide semiconductor thin-film transistor. The thin-film transistor 122 can be of an n-conductive type.

The image sensor 10 used as an X-ray imaging device reads a signal by making the thin-film transistor 122 in the pixel 13 conductive and taking out the signal charge generated and stored in the amount corresponding to the amount of light incident on the photodiode 121.

The driver circuit 14 selects the gate lines 105 one by one and applies a pulse to turn the thin-film transistor 122 into a conductive state. The anode terminal of the photodiode 121 is connected to a bias line 107 and the signal line 106 is supplied with a reference potential by the signal detector circuit 16. Accordingly, the photodiode 121 is charged by the difference voltage between the bias potential of the bias line 107 and the reference potential. This difference voltage is set to be the reverse-bias where the cathode potential is higher than the anode potential.

The charge required to recharge the photodiode 121 to the reverse-bias voltage depends on the amount of light incident on the photodiode 121. The signal detector circuit 16 reads the signal charge by integrating the current flowing in recharging the photodiode 121 to the reverse-biased state.

The signal charge stored in the photodiode 121 definitely decreases because of the incident light and dark-leak current that flows even when the photodiode 121 is not irradiated with light. Accordingly, in reading the signal charge, the voltage at the terminal of the thin-film transistor 122 connected to the signal line 106 is higher than the voltage at the terminal connected to the photodiode 121. Accordingly, in signal charge detection, the terminal connected to the signal line 106 is the drain and the terminal connected to the photodiode 121 is the source.

In the following description, the photodiode 121 and the thin-film transistor 122 included in the pixel 13 of an imaging element have multilayer structures.

### Structure of Imaging Element

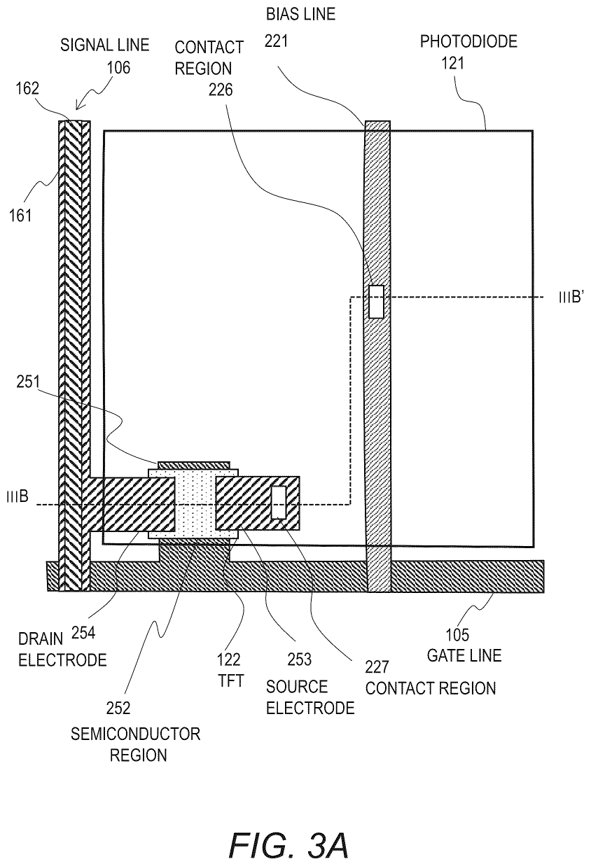

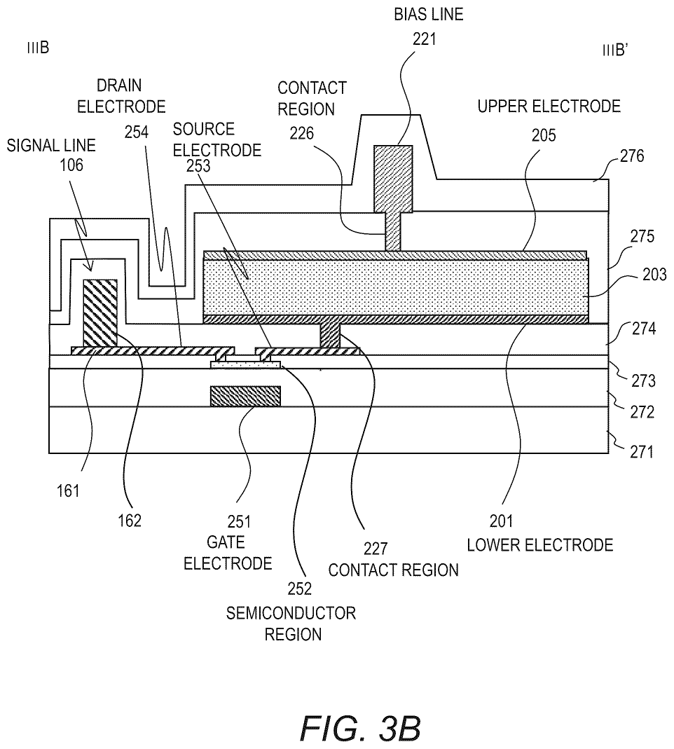

FIG. 3A is a plan diagram schematically illustrating the structure of a pixel including a photodiode 121, a thin-film transistor 122, a part of a gate line 105 and a part of a signal line 106 (see FIG. 2). In FIG. 3A, the signal line 106 extends vertically; the gate line 105 extends horizontally; and the thin-film transistor (TFT) 122 is disposed at their intersection. The thin-film transistor 122 includes a gate electrode 251, a semiconductor region 252, a source electrode 253, and a drain electrode 254.

The photodiode 121 is provided upper than the thin-film transistor 122 and covers at least a part of the thin-film transistor 122. In the configuration example in FIG. 3A, the photodiode 121 covers the entire source electrode 253 and semiconductor region 252 and a part of the drain electrode 254. The photodiode 121 in FIG. 3A is depicted transparently to show the elements thereunder.

Such a configuration that the photodiode 121 covers at least a part of the thin-film transistor 122, particularly at least a part of the drain electrode 254 in addition to the source electrode 253 and the semiconductor region 252, enables the photodiode 121 to have a larger light receiving area.

The pixel 13 further includes a bias line 221. The bias line 221 is provided upper than the photodiode 121 and connected to the upper electrode (not shown in FIG. 3A) of the photodiode 121 via a contact region 226. The contact region 226 is a conductive region in a contact hole opened through one or more insulating films.

The source electrode 253 is interconnected with the lower electrode (not shown in FIG. 3A) of the photodiode 121 through a contact region 227. The contact region 227 is a conductive region in a contact hole opened through one or more insulating films.

The signal line 106 includes a lower first signal line layer 161 and an upper second signal line layer 162. These layers are metal layers. The first signal line layer 161 is included in the same metal layer pattern as the drain electrode 254. This means that these are simultaneously produced of the same metal material. The first signal line layer 161 and the drain electrode 254 are unseparated. The second signal line layer 162 is included in a metal layer pattern different from the first signal line layer 161. The metal material of the first signal line layer 161 can have a higher specific resistance than the metal material of the second signal line layer 162. The same applies to the other embodiments and other configuration examples in this specification.

In the configuration example in FIG. 3A, the second signal line layer 162 has a narrower line width than the first signal line layer 161 and in a planar view, the left and right ends of the second signal line layer 162 are located within the plane of the first signal line layer 161. The line width is the horizontal size in FIG. 3A. As will be described later, no layer exists between the second signal line layer 162 and the first signal line layer 161 and these layers are in direct contact, not via a contact hole.

Employing a multilayer structure consisting of a plurality of metal layers for the signal line 106 attains a lower line resistance and improves the S/N ratio. In addition, not providing a contact hole connecting the second signal line layer 162 and the first signal line layer 161 enables the photodiode 121 to have a larger light receiving area.

FIG. 3B is a cross-sectional diagram along the section line IIIB-IIIB′ in FIG. 3A. In the subsequent drawings, the reference signs of some elements may be omitted. The thin-film transistor 122 includes a gate electrode 251 provided above a substrate 271 having insulating properties, a gate insulating film 272 above the gate electrode 251, and a semiconductor region 252 above the gate insulating film 272.

As illustrated in FIG. 3A, the gate electrode 251 is a part projecting upward from the horizontally extending gate line 105; the gate electrode 251 is continued from the gate line 105. The gate electrode 251 and the gate line 105 are formed on the insulating substrate (insulating film) 271 and they are included in the same conductive layer. A silicon insulating film can be provided between the insulating substrate 271 and the conductive layer of the gate electrode 251 and the gate line 105.

Unseparated or separate conductive regions included in the same conductive layer are made of the same material above and in direct contact with the same insulating layer. In manufacture, the conductive regions of the same conductive layer are produced in the same manufacturing step. The conductive layer can have a single-layer structure or a multilayer structure.

In this configuration example, the thin-film transistor 122 has a bottom-gate structure; the gate electrode 251 is located lower than the semiconductor region 252. The thin-film transistor 122 further includes electrodes 253 and 254 above the gate insulating film 272. The electrodes 253 and 254 are included in the same conductive layer.

Depending on the flow of carriers, one of the electrodes 253 and 254 is a source electrode and the other one is a drain electrode. In detecting the charge of the photodiode 121, the electrode 253 is a source electrode and the electrode 254 is a drain electrode. Accordingly, the electrode 253 is referred to as source electrode and the electrode 254 as drain electrode hereinafter.

The gate insulating film 272 is formed to fully cover the gate electrode 251. The gate insulating film 272 is provided between the gate electrode 251 and the semiconductor region 252.

The substrate 271 can be made of glass or resin. The gate electrode 251 is a conductor and can be made of a metal or silicon doped with impurities. The gate insulating film 272 can be a silicon oxide film, a silicon nitride film, or a multilayer film of these films. The semiconductor for the semiconductor region 252 can be an oxide semiconductor or amorphous silicon. The oxide semiconductor contains at least one of In, Ga, and Zn and examples of the oxide semiconductor include amorphous InGaZnO (a-InGaZnO) and microcrystalline InGaZnO.

A first interlayer insulating film 273 is provided to partially cover the gate insulating film 272 and the semiconductor region 252. The first interlayer insulating film 273 is made of an inorganic or organic insulator. The source electrode 253 and the drain electrode 254 are connected to the semiconductor region 252 through contact holes (contact regions) provided in the first interlayer insulating film 273. The first interlayer insulating film can be optional.

The source electrode 253 and the drain electrode 254 are conductors and can be a single-layer film of a metal such as Mo, Ti, Al, or Cr or an alloy thereof or a multilayer film of these materials. Although the thin-film transistor 122 illustrated in FIGS. 3A and 3B has a bottom-gate structure, the thin-film transistor 122 can have a top-gate structure or include both a top-gate electrode and a bottom-gate electrode.

The first signal line layer 161 of the signal line 106 is formed continuously from the drain electrode 254. The first signal line layer 161 and the drain electrode 254 are both provided above and in direct contact with the first interlayer insulating film 273; they have interfaces with the first interlayer insulating film 273. The first signal line layer 161 is made of the same material as the drain electrode 254 and structured continuously from the drain electrode 254.

The second signal line layer 162 is provided above and in direct contact with the first signal line layer 161 not via a contact hole opened through one or more insulating films. The under face of the second signal line layer 162 has an interface with the top face of the first signal line layer 161. The second signal line layer 162 can have a single-layer or multilayer structure and it can be a single-layer film of a metal such as Mo, Ti, Al, or Cu or an alloy thereof or a multilayer film of those materials.

Providing the second signal line layer 162 above and in direct contact with the first signal line layer 161 without a contact hole enables the photodiode 121 to have a larger area. Contact holes significantly affect the area of the photodiode 121. The inventors' research revealed that, in the case of 50-um pixel pitch, removing a contact hole between the second signal line layer 162 and the first signal line layer 161 produces improvement effect to increase the area of the photodiode 121 by 1.2 times.

In a planar view, the second signal line layer 162 does not overlap the photodiode 121 and it extends outside the light receiving region of the photodiode 121. The light receiving region is the region for the photodiode 121 to perform photoelectric conversion. The second signal line layer 162 has a larger thickness (film thickness) than the first signal line layer 161. This configuration allows the first signal line layer 161 to be thinner while keeping the resistance of the signal line 106 low. The thickness of the second signal line layer 162 can be equal to or smaller than the thickness of the first signal line layer 161. The same applies to the other embodiments and configuration examples in this specification.

This configuration avoids generation of a large height difference in the underlayer of the photodiode 121 in the overlap region of the photodiode 121 and the source electrode 253 or the drain electrode 254. For example, a height difference of approximately 1 um increases the leak current of the photodiode 121 by approximately five times, compared to a flat structure. High leak current of the photodiode 121 reduces the dynamic range and increases the noise, degrading the performance of the image sensor 10.

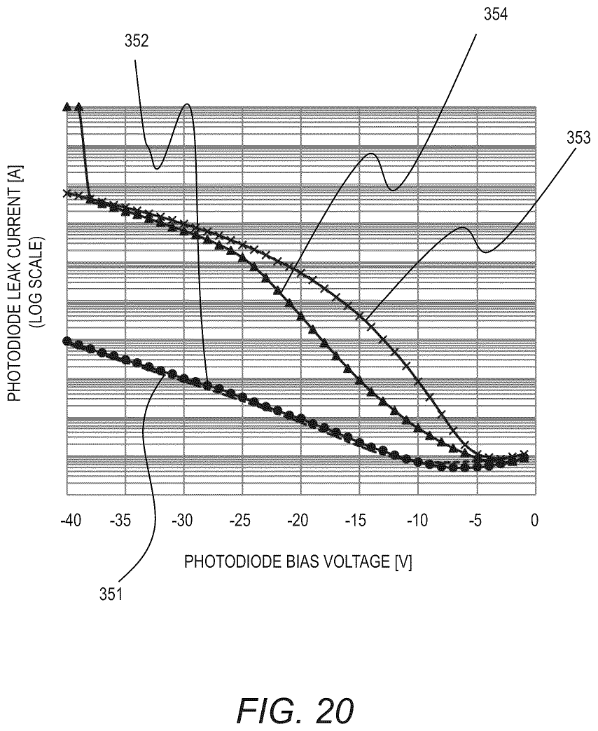

FIG. 20 provides experimental results on elements provided with a different height of step-like part in a layer under a photodiode having a thickness of 1 um and an element not provided with such a step-like part. The heights of the step-like parts of the elements were 0.2 um, 0.7 um, and 1.2 um. The experiment measured the leak current while varying the bias current applied to the photodiode. The curve 351 represents the experimental result on the element without a step-like part. The curves 352, 353, and 354 respectively represent the experimental results on the elements with 0.2-um, 0.7-um, and 1.2-um step-like parts. The element provided with a 0.2-um step-like part exhibited substantially the same result as the element without a step-like part, but the other elements exhibited significantly high leak current. Moreover, the element with a 1.2-um step-like part developed insulation breakdown when a high bias voltage is applied.

In the region of the photodiode film above the step-like part, an electric field concentration is likely to occur and the extent of the concentration is higher when the step-like part is higher. A low resistive signal line can be formed to have a thickness of 0.5 um to 1.0 um. Accordingly, the experimental results in FIG. 20 indicate that disposing the source electrode and drain electrode on the same metal layer having the same thickness as the signal line under the photodiode degrades the performance of the image sensor.

A second interlayer insulating film 274 is provided between the lower electrode 201 of the photodiode 121 and the thin-film transistor 122. The second interlayer insulating film 274 covers the entire signal line 106 and a part of the thin-film transistor 122 (the part except for the contact region) and it is in direct contact with these. The second interlayer insulating film 274 is made of an inorganic or organic insulator.

Especially in the case of forming a second interlayer insulating film 274 of an inorganic insulator, step-like parts are generated on the second interlayer insulating film 274 in accordance with the thicknesses of the elements of the thin-film transistor 122, such as the gate electrode 251, the drain electrode 254, and the source electrode 253. Therefore, these gate electrode 251, drain electrode 254, and source electrode 253 to be disposed under the second interlayer insulating film 274 are desirable to be formed as thin as possible.

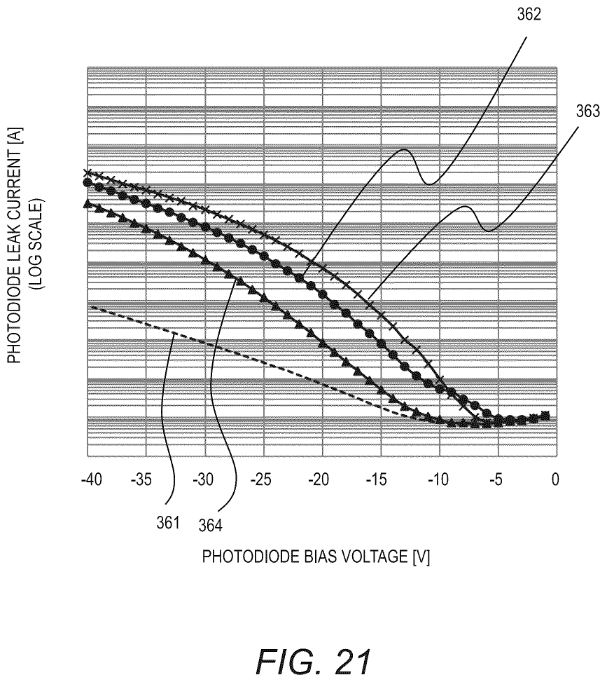

FIG. 21 provides experimental results on elements having a different thickness of inorganic interlayer insulating film between a photodiode having a thickness of 1 um and a layer including a step-like part having a height of 1 um under the photodiode and an element provided with neither a step-like part nor an inorganic interlayer insulating film. The thicknesses of the inorganic interlayer insulating films were 0.2 um, 0.7 um, and 1.2 um. The experiment measured the leak current while varying the bias current applied to the photodiode. The curve 361 represents the experimental result on the element provided with neither a step-like part nor an inorganic interlayer insulating film. The curves 362, 363, and 364 respectively represent the experimental results on the elements having 0.2-um, 0.7-um, and 1.2-um thicknesses of inorganic interlayer insulating films.

All the elements including a step-like part and an inorganic interlayer insulating film exhibited significantly high leak current, compared to the element not including a step-like part. Among the elements used in the experiment, the element including a 1.2-um interlayer insulating film exhibited relatively low leak current. However, the difference from the leak current of the element without a step-like part is large; it is inferred that the structure to cause electric field concentration is maintained.

Generally, covering a step-like part with a relatively thick film is expected to show an effect to smooth the height difference. However, the experimental results revealed that effect to suppress the leak current is not enough. A low resistive signal line can be formed to have a thickness of 0.5 um to 1.0 um. The experimental results in FIG. 21 indicate that, in the case where a source electrode and a drain electrode having the same thickness as the signal line are disposed on the same metal layer as the signal line, covering the drain electrode and the source electrode with an inorganic interlayer insulating film having a thickness of 0.2 um to 1.2 um, which is the thickness employed in common manufacture, does not suppress the leak current of the photodiode provided thereabove and cannot avoid degradation in performance of the image sensor.

The lower electrode 201 is connected to the source electrode 253 of the thin-film transistor 122 via the contact region 227 in the contact hole in the second interlayer insulating film 274.

The photodiode 121 consists of a photoelectric conversion region 203 sandwiched between the lower electrode 201 and the upper electrode 205 and the parts of the lower electrode 201 and the upper electrode 205 that are in contact with the photoelectric conversion region 203. The example of the photodiode 121 illustrated in FIG. 3B is a PIN diode. A PIN diode has a thick depletion layer in the film thickness to detect light efficiently. The upper electrode 205 is a transparent electrode for the light from the scintillator; it can be made of ITO.

The photoelectric conversion region 203 of the photodiode 121 includes an n-type amorphous silicon layer above the lower electrode 201, an intrinsic amorphous silicon layer above the n-type amorphous silicon layer, and a p-type amorphous silicon layer above the intrinsic amorphous silicon layer. The upper electrode 205 is provided above the p-type amorphous silicon layer. The light to be detected enters the photodiode 121 through the upper electrode 205. The locations of the n-type amorphous silicon layer and the p-type amorphous silicon layer can be opposite and further, the intrinsic amorphous silicon layer can be excluded.

A third interlayer insulating film 275 is provided to cover the photodiode 121 and the second interlayer insulating film 274. The third interlayer insulating film 275 is made of an inorganic or organic insulator. A bias line 221 is provided above the third interlayer insulating film 275. The bias line 221 is connected to the upper electrode 205 via a contact region 226 provided in a contact hole opened through the third interlayer insulating film 275. The bias line 221 is a conductor and can be a single-layer film of a metal such as Mo, Ti, Al, or Cu or an alloy thereof, or a multilayer film of those materials.

A passivation layer 276 is provided to cover the bias line 221 and the third interlayer insulating film 275. The passivation layer 276 covers the whole pixel region 12. The passivation layer 276 is made of an inorganic or organic insulator. A scintillator not shown in FIG. 3B is provided above the passivation layer 276.

The scintillator covers the whole pixel region 12. The scintillator emits light by being excited by radioactive rays. Specifically, the scintillator converts the received X-rays into light having a wavelength detectable for the photodiode 121. The photodiode 121 generates signal charge in the amount in accordance with the light from the scintillator and stores the signal charge.

The photodiode 121 in the above-described configuration example is located upper than the thin-film transistor 122. This disposition is advantageous because the attenuation of received light by the insulating layers is smaller. Moreover, in the semiconductor processes to manufacture the element, the thin-film transistor that requires high-temperature process is fabricated before the photodiode, film peel-off and/or degassing caused by contraction stress of the films can be avoided. Accordingly, the easiness and the quality in the manufacture are improved.

### Structural Examples of Semiconductor Thin-Film Transistor

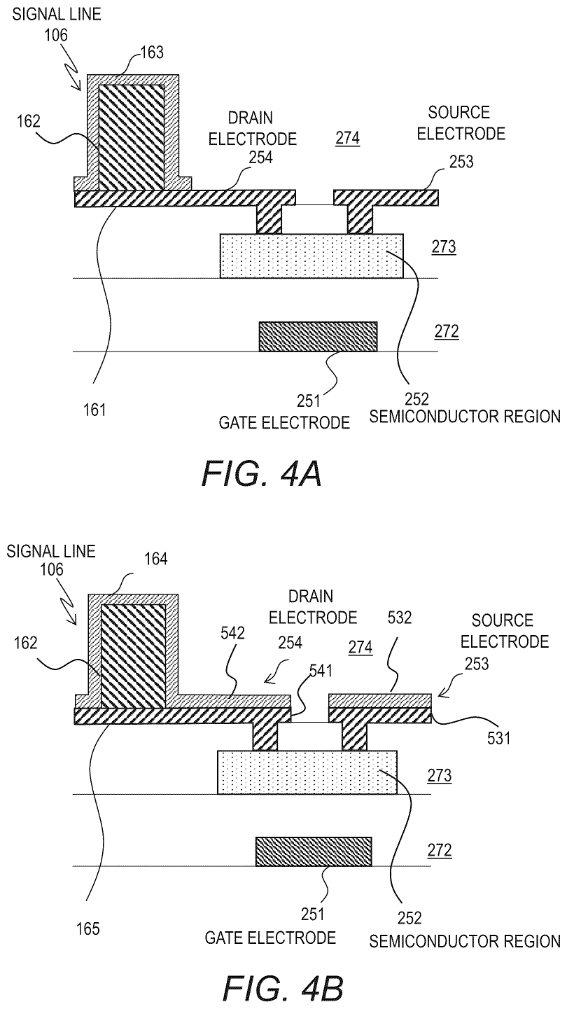

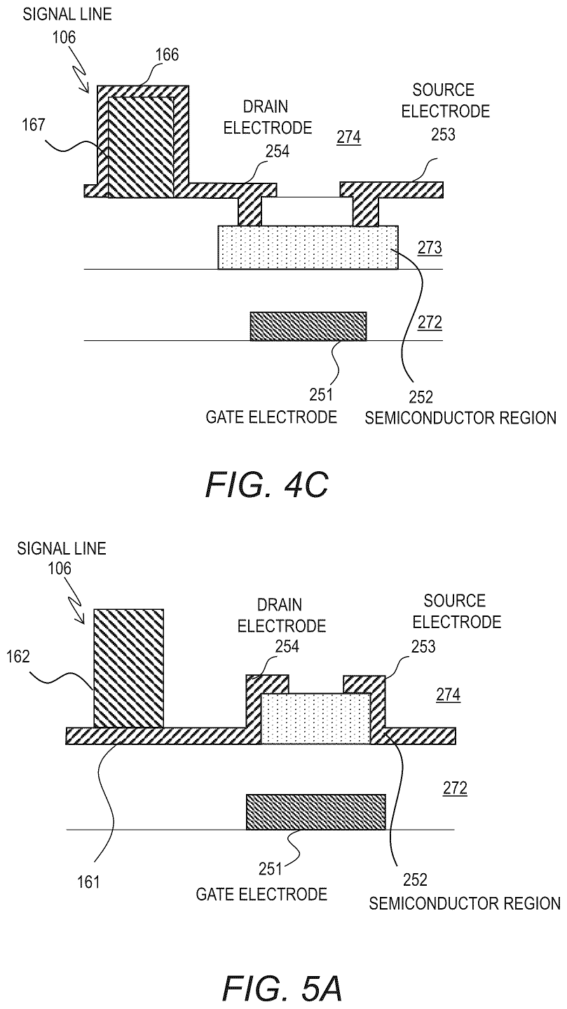

Hereinafter, some structural examples of a thin-film transistor that are applicable to a pixel 13 are described. FIG. 4A is a cross-sectional diagram schematically illustrating a structural example of a thin-film transistor and a signal line. Compared to the structure of a thin-film transistor in FIG. 3B, a third signal line layer 163 is added. For example, the second signal line layer 162 can have a single-layer structure of aluminum and the third signal line layer 163 can have a single-layer structure of a metal material such as Mo or Ti. The third signal line layer 163 is thinner than the second signal line layer 162.

The third signal line layer 163 is in direct contact with and covers the top and side faces of the second signal line layer 162. The metal layer pattern including the third signal line layer 163 covers neither the source electrode 253 nor the drain electrode 254. In other words, the source electrode 253 and the drain electrode 254 are located outside the metal layer pattern and their top faces are in direct contact with the second interlayer insulating film 274. For example, the metal layer pattern may consist of the third signal line layers 163 each covering the signal line 106.

FIG. 4B is a cross-sectional diagram schematically illustrating another structural example of a thin-film transistor and a signal line. The source electrode 253 includes a lower first source electrode layer 531 and an upper second source electrode layer 532. The top face of the first source electrode layer 531 has an interface with the under face of the second source electrode layer 532. For example, the source electrode 253 has a two-layer structure; the source electrode layers 531 and 532 are made of the same or different metal materials and each of them has a single-layer structure.

The drain electrode 254 includes a lower first drain electrode layer 541 and an upper second drain electrode layer 542. The top face of the first drain electrode layer 541 has an interface with the under face of the second drain electrode layer 542. For example, the drain electrode 254 has a two-layer structure; the drain electrode layers 541 and 542 are made of the same or different metal materials and each of them has a single-layer structure.

The signal line 106 includes a first signal line layer 165, a second signal line layer 162, and a third signal line layer 164. The third signal line layer 164 is in direct contact with and covers the top and side faces of the second signal line layer 162. For example, the second signal line layer 162 has a single-layer structure of aluminum and the third signal line layer 164 has a single-layer structure of a metal material such as Mo or Ti. The third signal line layer 164 is thinner than the second signal line layer 162.

The first source electrode layer 531, the first drain electrode layer 541, and the first signal line layer 165 are included in the same metal layer pattern and produced simultaneously. The first signal line layer 165 and the first drain electrode layer 541 are unseparated. The other configuration of the first signal line layer 165 is the same as the first signal line layer 161. The second source electrode layer 532, the second drain electrode layer 542, and the third signal line layer 164 are included in the same metal layer pattern and produced simultaneously. The third signal line layer 164 and the second drain electrode layer 542, are unseparated.

FIG. 4C is a cross-sectional diagram schematically illustrating still another structural example of a thin-film transistor and a signal line. The signal line 106 includes an upper first signal line layer 166 and a lower second signal line layer 167. The under face of the first signal line layer 166 is in direct contact with the top face of the second signal line layer 167. The first signal line layer 166 covers the top and side faces of the second signal line layer 167. The under face of the second signal line layer 167 is in direct contact with the top face of the first interlayer insulating film 273.

The first signal line layer 166 is included in the same metal layer pattern as the source electrode 253 and the drain electrode 254; these are simultaneously produced of the same material. The first signal line layer 166 and the drain electrode 254 are unseparated. For example, each of the first signal line layer 166 and the second signal line layer 167 has a single-layer structure and made of a different metal material. For example, the first signal line layer 166 can be made of molybdenum and the second signal line layer 167 can be made of aluminum.

In the structural examples of a pixel in FIGS. 3B and 4A to 4C, a first interlayer insulating film 273 is interposed between the semiconductor layer and the layer of the source electrode and the drain electrode. The following describes some structural examples of a pixel that do not include the first interlayer insulating film 273.

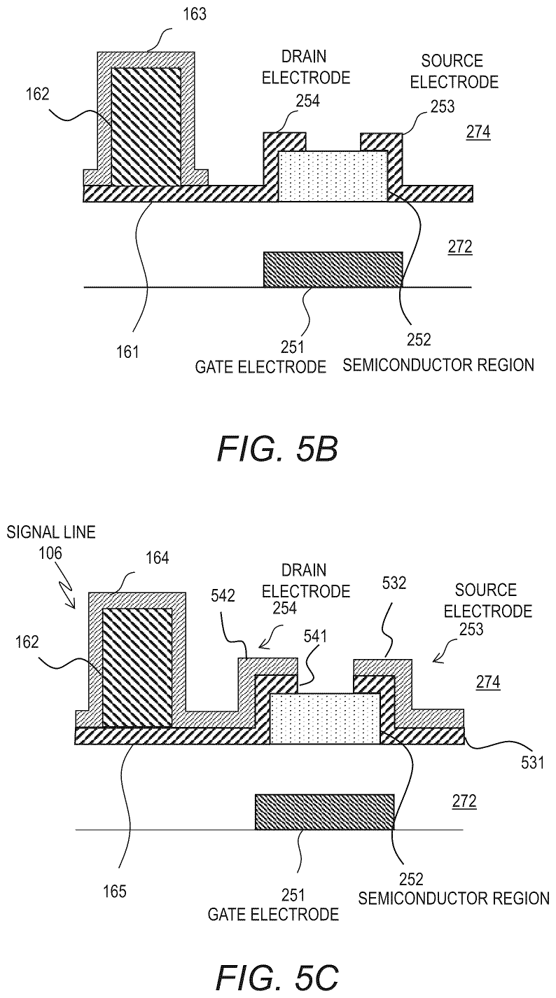

FIG. 5A is a cross-sectional diagram schematically illustrating still another structural example of a thin-film transistor and a signal line. Compared to the structural example in FIG. 3B, the first interlayer insulating film 273 is excluded. For this reason, parts of the under faces of the source electrode 253 and the drain electrode 254 are in direct contact with different parts of the surface of the semiconductor region 252. A part of the under face of the source electrode 253 is in direct contact with the top face and a side face of the semiconductor region 252. A part of the under face of the drain electrode 254 is in direct contact with the top face and another side face of the semiconductor region 252. The other parts of the under faces of the source electrode 253 and the drain electrode 254 are in direct contact with the top face of the gate insulating film 272.

FIG. 5B is a cross-sectional diagram schematically illustrating still another structural example of a thin-film transistor and a signal line. Compared to the structural example in FIG. 5A, a third signal line layer 163 is added. For example, the second signal line layer 162 can have a single-layer structure of aluminum and the third signal line layer 163 can have a single-layer structure of a metal material such as Mo or Ti. The third signal line layer 163 is thinner than the second signal line layer 162.

The third signal line layer 163 is in direct contact with and covers the top and side faces of the second signal line layer 162. The metal layer pattern including the third signal line layer 163 covers neither the source electrode 253 nor the drain electrode 254. In other words, the source electrode 253 and the drain electrode 254 are located outside the metal layer pattern and their top faces are in direct contact with the second interlayer insulating film 274. For example, the metal layer pattern may consist of the third signal line layers 163 each covering the signal line 106.

FIG. 5C is a cross-sectional diagram schematically illustrating still another structural example of a thin-film transistor and a signal line. The source electrode 253 includes a lower first source electrode layer 531 and an upper second source electrode layer 532. The top face of the first source electrode layer 531 has an interface with the under face of the second source electrode layer 532. For example, the source electrode 253 has a two-layer structure; the source electrode layers 531 and 532 are made of the same or different metal materials and each of them has a single-layer structure.

The drain electrode 254 includes a lower first drain electrode layer 541 and an upper second drain electrode layer 542. The top face of the first drain electrode layer 541 has an interface with the under face of the second drain electrode layer 542. For example, the drain electrode 254 has a two-layer structure; the drain electrode layers 541 and 542 are made of the same or different metal materials and each of them has a single-layer structure.

Parts of the under faces of the first source electrode layer 531 and the first drain electrode layer 541 are in direct contact with different parts of the surface of the semiconductor region 252. A part of the under face of the first source electrode layer 531 is in direct contact with the top face and a side face of the semiconductor region 252. A part of the under face of the first drain electrode layer 541 is in direct contact with the top face and another side face of the semiconductor region 252. The other parts of the under faces of the first source electrode layer 531 and the first drain electrode layer 541 are in direct contact with the top face of the gate insulating film 272.

The signal line 106 includes a first signal line layer 165, a second signal line layer 162, and a third signal line layer 164. The third signal line layer 164 is in direct contact with and covers the top and side faces of the second signal line layer 162. For example, the second signal line layer 162 has a single-layer structure of aluminum and the third signal line layer 164 has a single-layer structure of a metal material such as Mo or Ti. The third signal line layer 164 is thinner than the second signal line layer 162.

The first source electrode layer 531, the first drain electrode layer 541, and the first signal line layer 165 are included in the same metal layer pattern and produced simultaneously. The first signal line layer 165 and the first drain electrode layer 541 are unseparated. The other configuration of the first signal line layer 165 is the same as the first signal line layer 161. The second source electrode layer 532, the second drain electrode layer 542, and the third signal line layer 164 are included in the same metal layer pattern and produced simultaneously. The third signal line layer 164 and the second drain electrode layer 542 are unseparated.

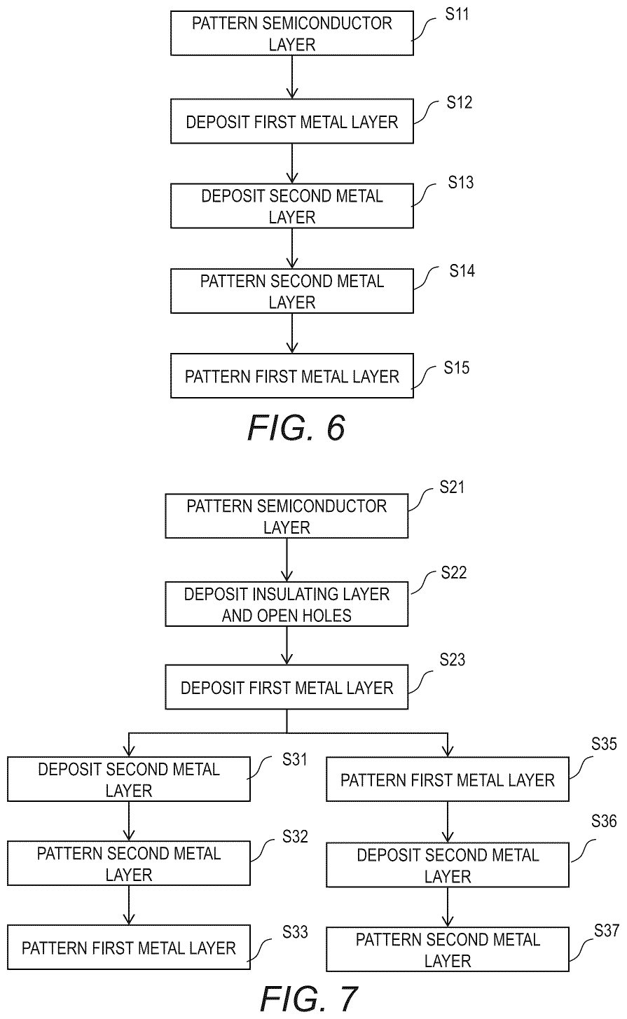

Some methods to manufacture the above-described different structural examples of a thin-film transistor are described. FIG. 6 is a flowchart for explaining a manufacturing method applicable to structures that do not include the first interlayer insulating film 273, such as the structural examples in FIGS. 5A, 5B, and 5C. The following description is provided with reference to the structural example in FIG. 5A.

After producing the metal layer pattern including the gate electrode 251 and the gate insulating film 272, the method patterns the semiconductor layer including the semiconductor region 252 (S11). Next, the method deposits a first metal layer including the first signal line layer 161, the source electrode 253, and the drain electrode 254 (S12). Next, the method deposits a second metal layer including the second signal line layer 162 (S13). Next, the method patterns the second metal layer (S14) and thereafter, patterns the first metal layer (S15).

Next, a method to manufacture a structure including the first interlayer insulating film 273 is described. FIG. 7 is a flowchart for explaining a manufacturing method applicable to the structural examples in FIGS. 3B, 4A, and 4B. The following description is provided with reference to the structural example in FIG. 3B.

After producing the metal layer pattern including the gate electrode 251 and the gate insulating film 272, the method patterns the semiconductor layer including the semiconductor region 252 (S21). Next, the method deposits an insulating layer and opens contact holes for the contact region 227 to produce the first interlayer insulating film 273 (S22). Next, the method deposits a first metal layer including the first signal line layer 161, the source electrode 253, and the drain electrode 254 (S23). After Step S23, there are two ways.

In the first way, the method deposits a second metal layer including the second signal line layer 162 (S31). Next, the method patterns the second metal layer (S32) and thereafter, patterns the first metal layer (S33). In the second way, the method first patterns the first metal layer (S35). Next, the method deposits a second metal layer including the second signal line layer 162 (S36) and patterns the second metal layer (S37).

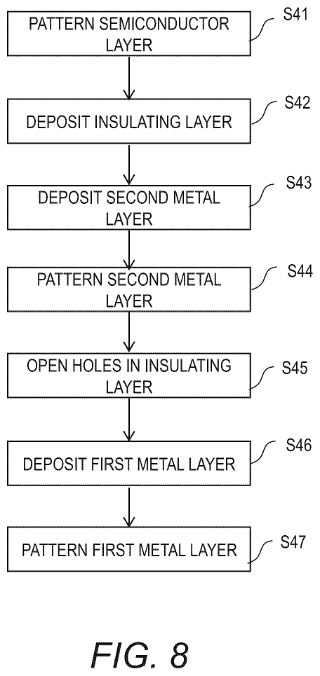

Another method to manufacture a structure including the first interlayer insulating film 273 is described. FIG. 8 is a flowchart for explaining a manufacturing method applicable to the structural example in FIG. 4C. After producing the metal layer pattern including the gate electrode 251 and the gate insulating film 272, the method patterns the semiconductor layer including the semiconductor region 252 (S41).

Next, the method deposits an insulating layer including the first interlayer insulating film 273 (S42). Next, the method deposits a second metal layer including the second signal line layer 167 (S43). Next, the method patterns the second metal layer to form the metal layer pattern including the second signal line layer 167 (S44). Next, the method opens contact holes in the insulating layer including the first interlayer insulating film 273 (S45). Next, the method deposits a first metal layer including the source electrode 253, the drain electrode 254, and the first signal line layer 166 (S46). Next, the method patterns the first metal layer to form a metal layer pattern including the source electrode 253, the drain electrode 254, and the first signal line layer 166 (S47).

The manufacturing method in FIG. 7 or 8 eliminates the concern about exposure of the semiconductor layer and improves the process selectivity. The manufacturing method in FIG. 8 enables employment of a material that does not have etching selectivity for the first metal layer including the first signal line layer 166 and the second metal layer including the second signal line layer 167, achieving manufacturing easiness.

### Other Structural Examples of Imaging Element

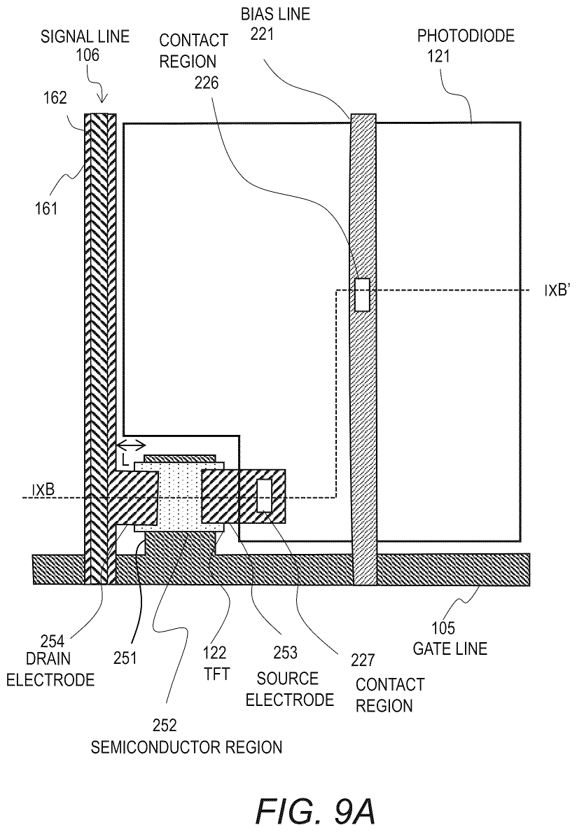

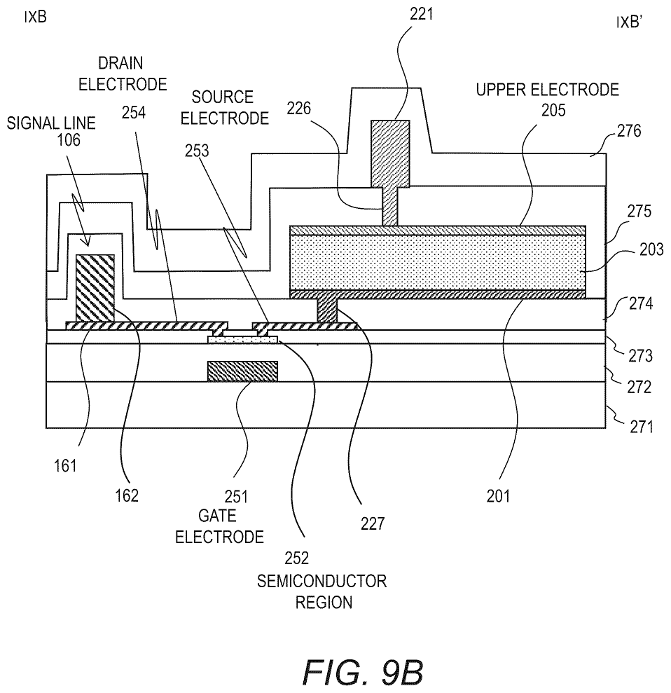

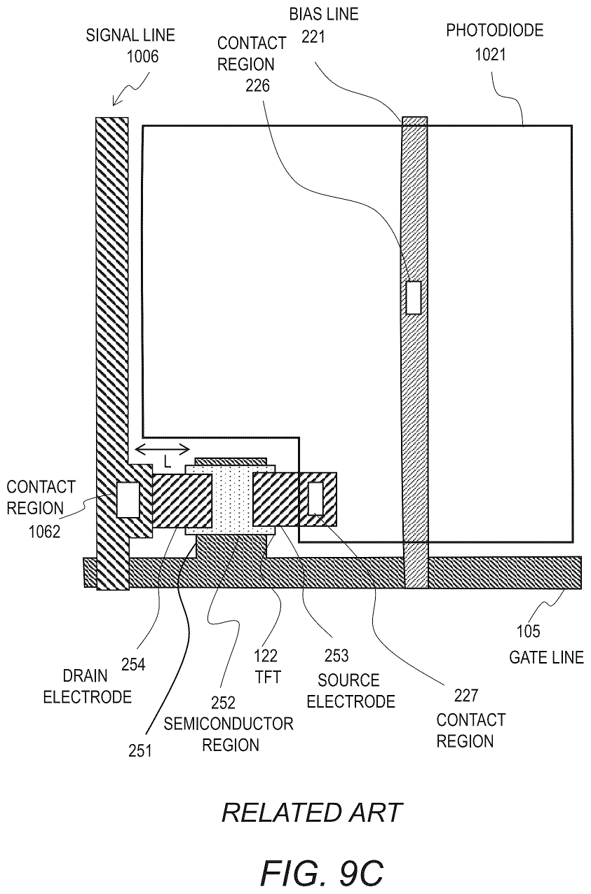

FIG. 9A is a plan diagram schematically illustrating another structural example of an imaging element. Differences from the structural example described with reference to FIGS. 3A and 3B are mainly described. FIG. 9B schematically illustrates the cross-sectional structure along the section line IXB-IXB′ in FIG. 9A.

Compared to the structural example in FIGS. 3A and 3B, the photodiode 121 (the upper electrode 205 and the lower electrode 201 thereof) only covers a part of the source electrode 253 of the thin-film transistor 122 and covers neither the semiconductor region 252 nor the drain electrode 254 in a planar view. In other words, these are disposed outside the region of the photodiode 121. The photodiode 121 does not overlap the second signal line layer 162 of the signal line 106 and the second signal line layer 162 is distant from the photodiode 121 in a planar view. The second signal line layer 162 is thicker than the source electrode 253. This configuration can eliminate a high step-like part from the photodiode 121.

A structural example of a related art is described. FIG. 9C is a plan diagram schematically illustrating a pixel structure of a related art. In the structural example of the related art in FIG. 9C, the signal line 1006 has a structure different from the structure of the signal line 106 in the structural example in FIG. 9A. The signal line 1006 does not include the metal layer of the drain electrode 254 and it is connected to the drain electrode 254 via a contact region 1062 provided in a contact hole.

The structural example in FIGS. 9A and 9B does not include the contact region 1062 (contact hole) shown in the related art in FIG. 9C. Excluding the contact hole for interconnecting the signal line 106 and the drain electrode 254 enables the distance L between the signal line 106 and the thin-film transistor 122 to be shorter than the distance L between the signal line 1006 and the thin-film transistor 122 in the related art. Hence, the photodiode 121 can have a larger area.

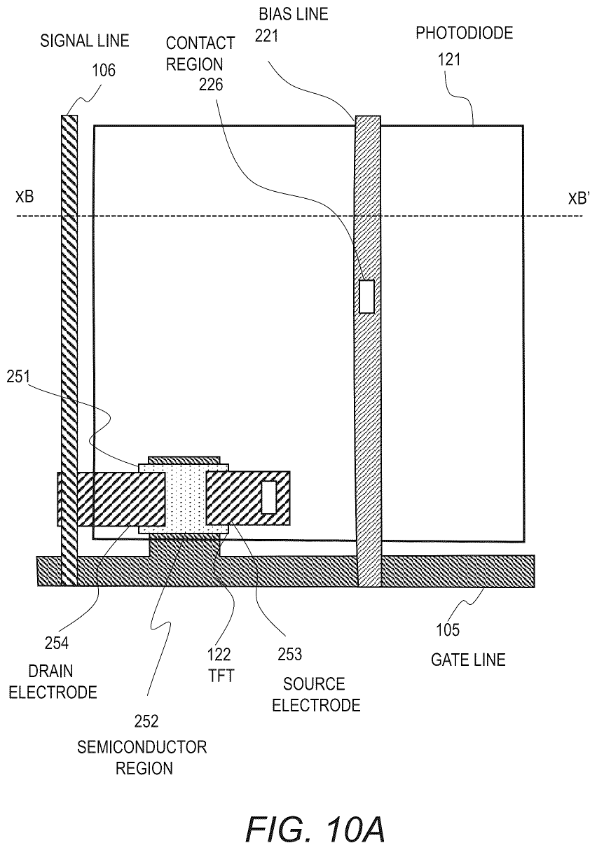

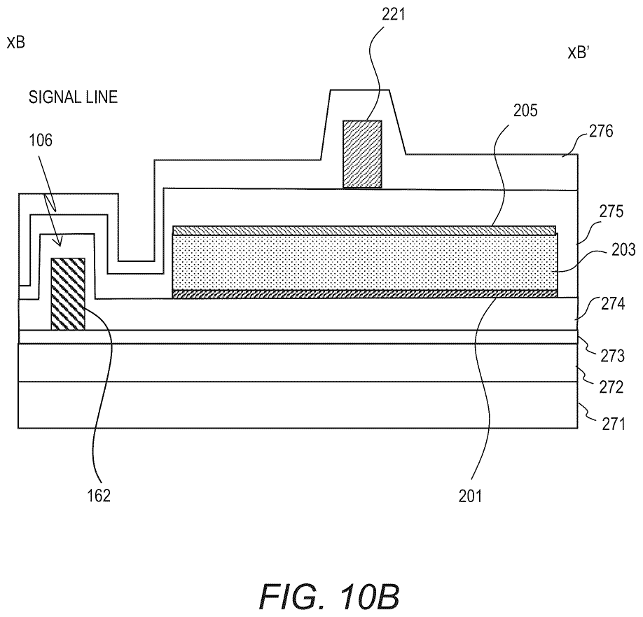

FIG. 10A is a plan diagram schematically illustrating still another structural example of an imaging element. Differences from the structural example described with reference to FIGS. 3A and 3B are mainly described. FIG. 10B schematically illustrates the cross-sectional structure along the section line XB-XB′ in FIG. 10A. The cross-sectional structure of the part including a thin-film transistor 122 is the same as the one described with reference to FIG. 3B.

As noted from FIGS. 3B and 10B, the signal line 106 includes a first signal line layer 161 only in a region in a planar view and does not include the first signal line layer 161 in the other region. Specifically, the signal line 106 only consists of the second signal line layer 162 in the region between the thin-film transistors 122 of the pixels 13 adjacent to each other in the vertical direction along which the signal line 106 extends. In this region, most of the signal line 106 has the same line width as the second signal line layer 162. In the interconnection region where the signal line 106 and the thin-film transistor 122 are in direct contact with each other, the signal line 106 has a two-layer structure. The largest value of the width of the signal line 106 is determined by the width of the first signal line layer 161 in the interconnection region with the thin-film transistor 122.

### Embodiment 2

Hereinafter, some structural examples of a pixel 13 of an imaging element are described. In the structural examples described in the following, the signal line connected to a thin-film transistor column (vertically aligned thin-film transistors) has an edge defined by the second signal line layer on the opposite side of the connected thin-film transistor column. In a planar view, the edge of the signal line coincides with the edge of the second signal line layer. The second signal line layer has a width equal to or wider than the width of the first signal line layer. This configuration enables reduction in resistance or thickness of the signal line. Alternatively, avoiding increase in resistance of the signal line and enlargement of the light receiving area of the photodiode are attained together.

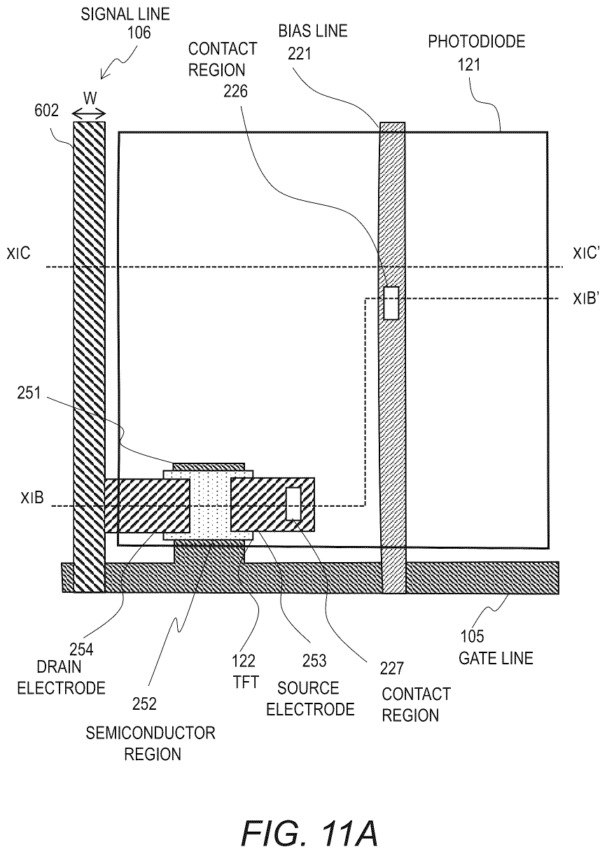

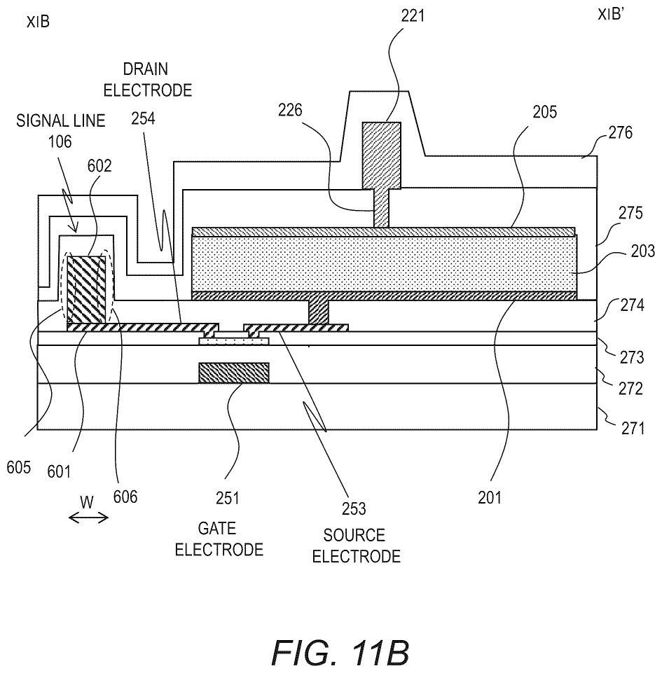

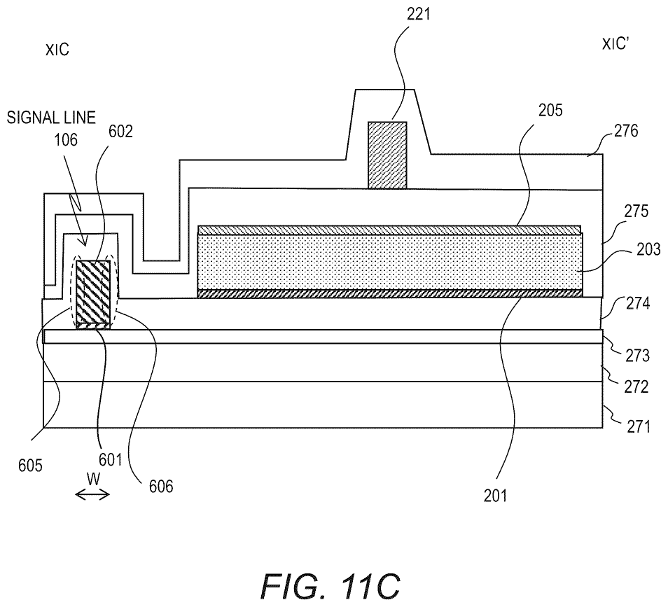

FIGS. 11A, 11B, and 11C illustrate the structure of a pixel 13 of an imaging element in an embodiment of this specification. FIG. 11B schematically illustrates the cross-sectional structure along the section line XIB-XIB′ in the plan diagram of FIG. 11A. FIG. 11C schematically illustrates the cross-sectional structure along the section line XIC-XIC′ in the plan diagram of FIG. 11A. The following mainly describes differences from the structural example described with reference to FIGS. 3A and 3B.

In this structural example, the width W of the second signal line layer 602 is equal to the width of the first signal line layer 601. The width is the horizontal size in FIGS. 11A, 11B, and 11C. In a planar view, the left edge 605 and the right edge 606 defining the width W of the second signal line layer 602 coincide with the edges defining the width of the first signal line layer 601. In other words, the edges defining the width of the signal line 106 coincide with the edges 605 and 606 defining the width of the second signal line layer 602. The right edge 606 is the edge closer to the photodiode to which the signal line 106 is connected and the left edge 605 is the edge closer to the photodiode adjacent in the horizontal direction. The signal line 106 extends between the connected photodiode and the adjacent photodiode.

Some structural examples of a thin-film transistor are described. In the following structural examples, between the two edges defining the width of a signal line 106, the edge on the opposite side of the thin-film transistor 122 to which the signal line 106 is connected is an edge of the second signal line layer in a meal layer pattern that is different from the metal layer pattern including the drain electrode.

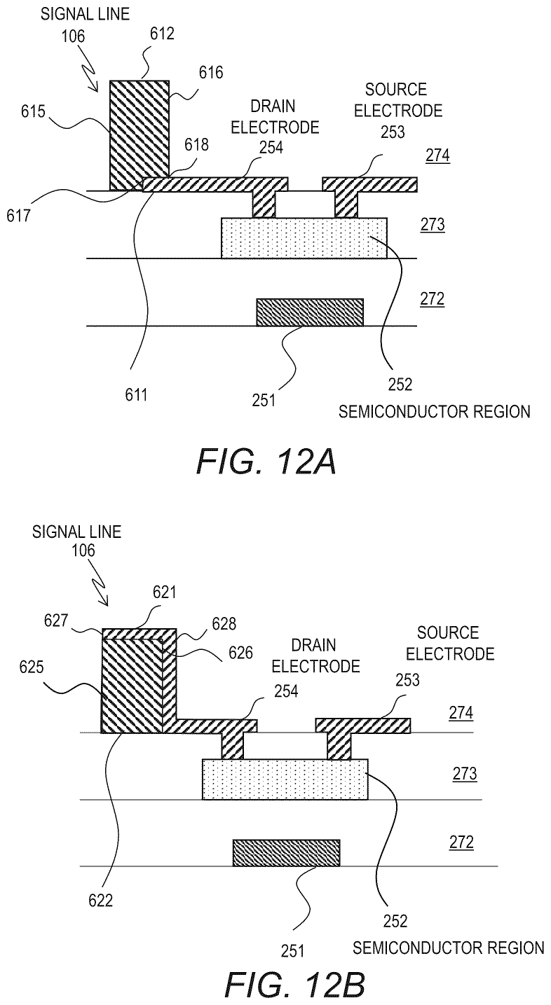

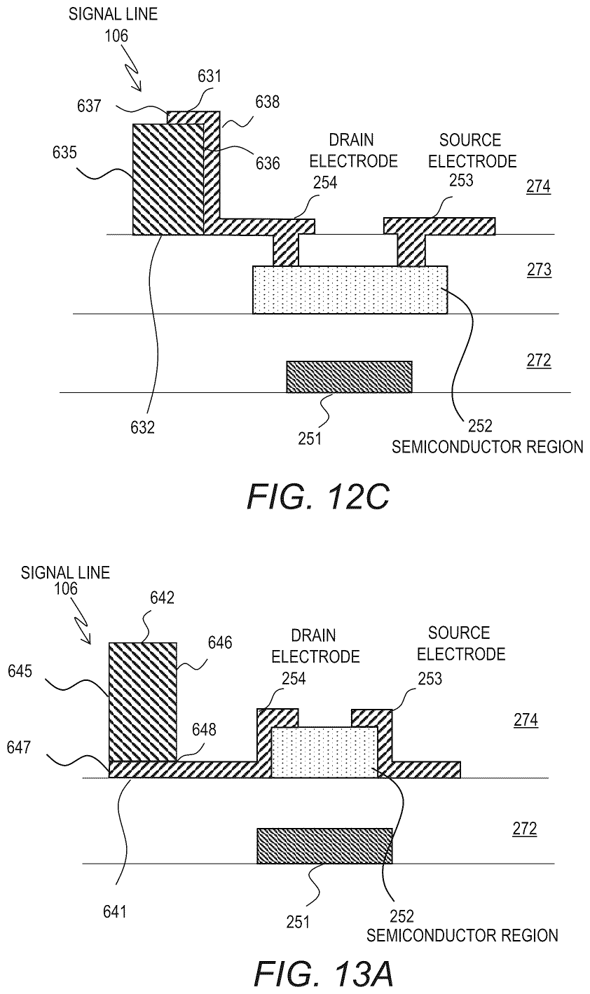

FIG. 12A is a cross-sectional diagram schematically illustrating a structural example of a thin-film transistor and a signal line. The signal line 106 consists of a first signal line layer 611 and a second signal line layer 612. A part of the under face of the second signal line layer 612 has an interface with the top face of the first signal line layer 611 and the other part has an interface with the top face of the first interlayer insulating film 273. The second signal line layer 612 is thicker than the first signal line layer 611. The first signal line layer 611 is included in the same metal layer pattern as the source electrode 253 and the drain electrode 254.

The left edge 617 of the first signal line layer 611 is covered with the second signal line layer 612 in a planar view (when viewed in the layering direction). The right edge 616 of the second signal line layer 612 coincides with the right edge 618 of the first signal line layer 611 in a planar view. The left edge 615 of the second signal line layer 612 is the left edge of the signal line 106.

FIG. 12B is a cross-sectional diagram schematically illustrating another structural example of a thin-film transistor and a signal line. The signal line 106 consists of a first signal line layer 621 and a second signal line layer 622. The first signal line layer 621 is in direct contact with and covers the top face and the side face defining the right edge 626 of the second signal line layer 622. The side face defining the left edge 625 of the second signal line layer 622 is not covered with the first signal line layer 621 and is exposed from the first signal line layer 621. The under face of the second signal line layer 622 is in direct contact with the first interlayer insulating film 273.

The second signal line layer 622 is thicker than the first signal line layer 621. The first signal line layer 621 is included in the same metal layer pattern as the source electrode 253 and the drain electrode 254. The left edge 627 of the first signal line layer 621 coincides with the left edge 625 of the second signal line layer 622 in a planar view. The left edge 625 of the second signal line layer 622 is the left edge of the signal line 106.

FIG. 12C is a cross-sectional diagram schematically illustrating still another structural example of a thin-film transistor and a signal line. The signal line 106 consists of a first signal line layer 631 and a second signal line layer 632. The first signal line layer 631 is in direct contact with and covers a part of the top face and the side face defining the right edge 636 of the second signal line layer 632. The side face defining the left edge 635 and the other part of the top face of the second signal line layer 632 are exposed from the first signal line layer 631.

The under face of the second signal line layer 632 is in direct contact with the first interlayer insulating film 273. The second signal line layer 632 is thicker than the first signal line layer 631. The first signal line layer 631 is included in the same metal layer pattern as the source electrode 253 and the drain electrode 254.

The left edge 637 of the first signal line layer 631 is located on the top face of the second signal line layer 632 and it is closer to the drain electrode 254 than the left edge 635 of the second signal line layer 632 in a planar view. The left edge 635 of the second signal line layer 632 is the left edge of the signal line 106.

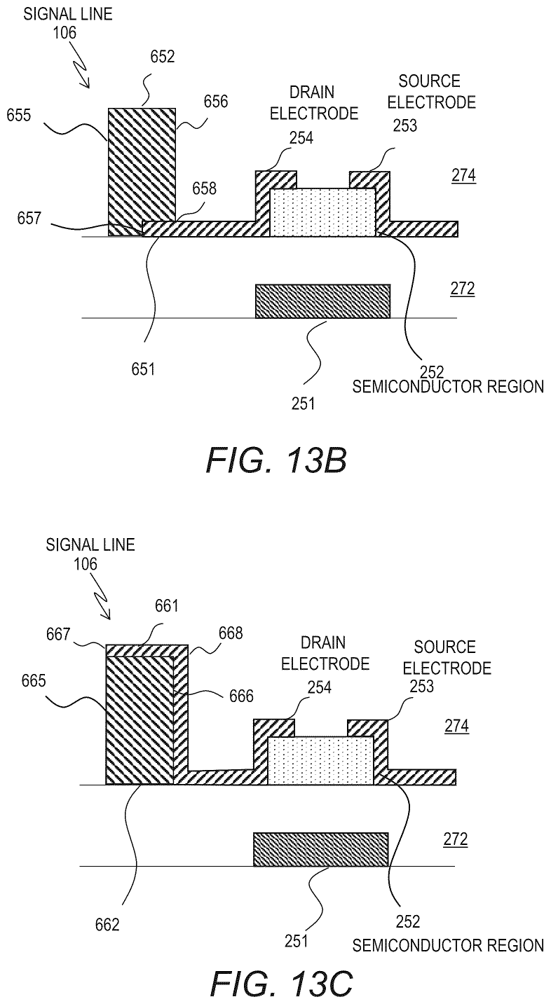

Some structural examples that do not include a first interlayer insulating film 273 are described. FIG. 13A is a cross-sectional diagram schematically illustrating a structural example of a thin-film transistor and a signal line. Compared to the structural example in FIG. 11B, the first interlayer insulating film 273 is excluded. For this reason, parts of the under faces of the source electrode 253 and the drain electrode 254 are in direct contact with different parts of the surface of the semiconductor region 252. A part of the under face of the source electrode 253 is in direct contact with the top face and a side face of the semiconductor region 252. A part of the under face of the drain electrode 254 is in direct contact with the top face and another side face of the semiconductor region 252. The other parts of the under faces of the source electrode 253 and the drain electrode 254 are in direct contact with the top face of the gate insulating film 272.

The signal line 106 consists of a first signal line layer 641 and a second signal line layer 642. The under face of the second signal line layer 642 has an interface with the top face of the first signal line layer 641. The second signal line layer 642 is thicker than the first signal line layer 641. The first signal line layer 641 is included in the same metal layer pattern as the source electrode 253 and the drain electrode 254.

The left edge 647 of the first signal line layer 641 coincides with the left edge 645 of the second signal line layer 642 in a planar view. The right edge 646 of the second signal line layer 642 coincides with the right edge 648 of the first signal line layer 641 in a planar view. The left edge 645 of the second signal line layer 642 is the left edge of the signal line 106.

FIG. 13B is a cross-sectional diagram schematically illustrating another structural example of a thin-film transistor and a signal line. Like the structural example in FIG. 13A, the first interlayer insulating film 273 is excluded. The signal line 106 consists of a first signal line layer 651 and a second signal line layer 652. A part of the under face of the second signal line layer 652 has an interface with the top face of the first signal line layer 651 and the other part has an interface with the top face of the gate insulating film 272. The second signal line layer 652 is thicker than the first signal line layer 651. The first signal line layer 651 is included in the same metal layer pattern as the source electrode 253 and the drain electrode 254.

The left edge 657 of the first signal line layer 651 is covered with the second signal line layer 652 in a planar view (when viewed in the layering direction). The right edge 656 of the second signal line layer 652 coincides with the right edge 658 of the first signal line layer 651 in a planar view. The left edge 655 of the second signal line layer 652 is the left edge of the signal line 106.

FIG. 13C is a cross-sectional diagram schematically illustrating still another structural example of a thin-film transistor and a signal line. Like the structural examples in FIGS. 13A and 13B, the first interlayer insulating film 273 is excluded. The signal line 106 consists of a first signal line layer 661 and a second signal line layer 662. The first signal line layer 661 is in direct contact with and covers the top face and the side face defining the right edge 666 of the second signal line layer 662. The side face defining the left edge 665 of the second signal line layer 662 is exposed from the first signal line layer 661. The under face of the second signal line layer 662 is in direct contact with the gate insulating film 272.

The second signal line layer 662 is thicker than the first signal line layer 661. The first signal line layer 661 is included in the same metal layer pattern as the source electrode 253 and the drain electrode 254. The left edge 667 of the first signal line layer 661 coincides with the left edge 665 of the second signal line layer 662 in a planar view. The left edge 665 of the second signal line layer 662 is the left edge of the signal line 106.

### Embodiment 3

Hereinafter, another structural example of a pixel 13 of an imaging element is described. In the structural example described in the following, each of the source electrode and the drain electrode is covered with an insulating film disposed between the first signal line layer and the second signal line layer. This structure enables simultaneous etching of the metal layer including the source electrode, drain electrode and first signal line layer and the metal layer including the second signal line layer.

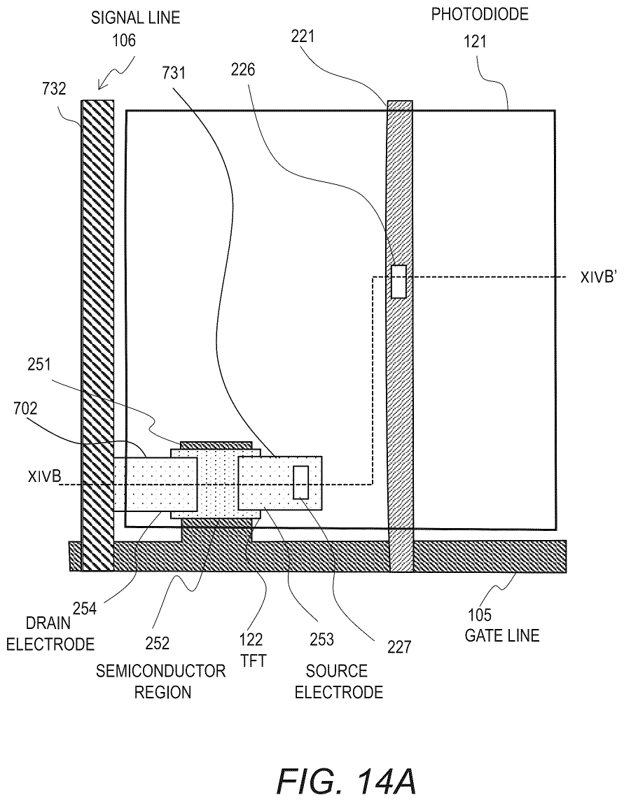

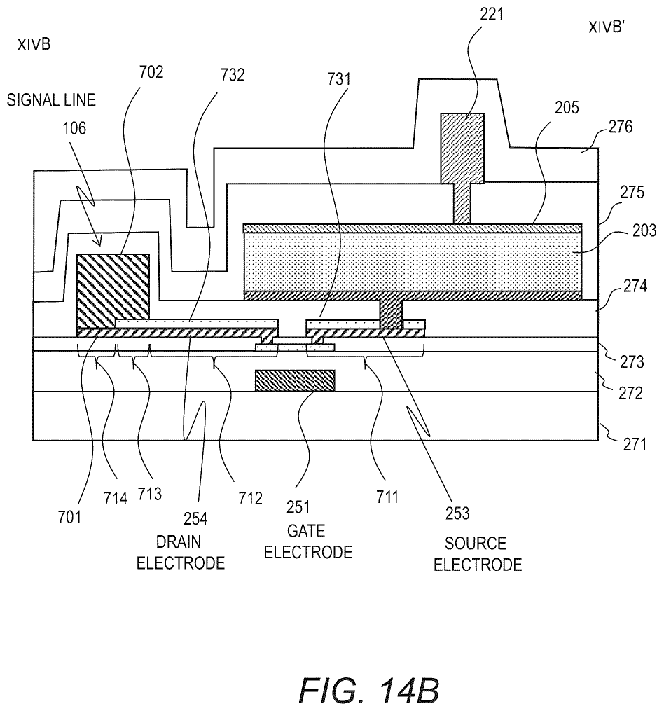

FIGS. 14A and 14B illustrate the structure of a pixel 13 of an imaging element in an embodiment of this specification. FIG. 14B schematically illustrates the cross-sectional structure along the section line XIVB-XIVB′ in the plan diagram of FIG. 14A. The following mainly describes differences from the structural example described with reference to FIGS. 11A, 11B, and 11C. FIG. 11C and the description provided with reference to FIG. 11C are applicable to this structural example.

Compared to the structural example described with reference to FIGS. 11A, 11B, and 11C, this structural example further includes insulating films 731 and 732. The insulating films 731 and 732 are included in the same insulating layer pattern and made of the same material, for example silicon oxide or silicon nitride.

The insulating film 731 covers the top face of the source electrode 253 in the region except for the region of the contact region 227. The under face of the insulating film 731 has an interface with the top face of the source electrode 253. The insulating film 732 covers the entire top face of the drain electrode 254. The under face of a part of the insulating film 732 has an interface with the top face of the drain electrode 254 as illustrated in FIG. 14B. The other part of the insulating film 732 is located between the first signal line layer 701 and the second signal line layer 702.

With reference to FIG. 14B, the signal line 106 consists of the first signal line layer 701 and the second signal line layer 702. The first signal line layer 701 is included in the same metal layer pattern as the drain electrode 254 and it is continued from the drain electrode 254. The first signal line layer 701 is thinner than the second signal line layer 702. In a planar view, the left edge of the first signal line layer 701 coincides with the left edge of the second signal line layer 702.

Regarding the first signal line layer 701, the region 713 is covered with the insulating film 732; the region 714 is not covered with the insulating film 732 and has an interface with the second signal line layer 702. The region 713 is located between the left edge region 714 and the drain electrode 254. The region 712 is a region of the drain electrode 254 and is fully covered with the insulating film 732. The region 711 is a region of the source electrode 253 and is fully covered with the insulating film 731.

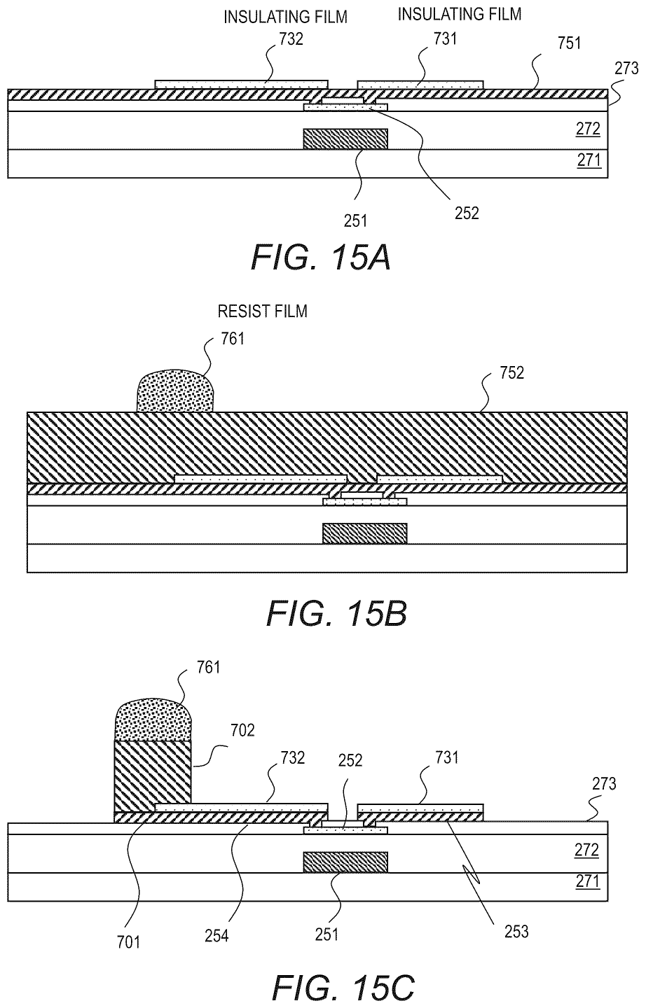

A manufacturing method of the structural example in FIGS. 14A and 14B is described. FIGS. 15A, 15B, and 15C illustrate steps in the manufacturing method. The insulating films are produced by CVD and the metal films are produced by sputtering, for example.

With reference to FIG. 15A, after producing a gate electrode 251, a gate insulating film 272, a semiconductor region 252, and a first interlayer insulating film 273 on a substrate 271, the method deposits a first metal film 751. The first metal film 751 includes a source electrode 253, a drain electrode 254, and a first signal line layer 701 to be formed later. The first metal film 751 is connected to the semiconductor region 252 via contact holes opened through the first interlayer insulating film 273.

Next, the method produces an insulating layer pattern including insulating films 731 and 732 above the first metal film 751. The insulating layer pattern can be produced by depositing a silicon insulating film by CVD and etching the silicon insulating film using a photoresist.

Next, as illustrated in FIG. 15B, the method deposits a second metal film 752 covering the entire substrate and forms a resist film 761 on the top face of the second metal film 752. The resist film 761 covers the region corresponding to the second signal line layer 702. The method etches the second signal line layer 702 using the resist film 761 to form a metal layer pattern including the second signal line layer 702. In this process, the insulating films 731 and 732 work as masks for the source electrode 253 and the drain electrode 254.

As described above, the method simultaneously patterns the first metal film 751 and the second metal film 752 using the resist film 761 and the insulating films 731 and 732 to form the signal line layers 701 and 702, the source electrode 253, and the drain electrode 254 as illustrated in FIG. 15C.

### Embodiment 4

Hereinafter, still another structural example of a pixel 13 of an imaging element is described. The following mainly describes differences from the structural example described with reference to FIGS. 14A and 14B. In the structural example described in the following, the insulating layer pattern between the first metal layer pattern including the first signal line layer 701, the source electrode 253, and the drain electrode 254 and the second metal layer pattern including the second signal line layer 702 covers a larger area. More specifically, the insulating layer pattern covers the entire region of the pixel 13 except for the part where an edge of the first metal layer pattern coincides with an edge of the second metal layer pattern in a planar view and the neighboring region thereof.

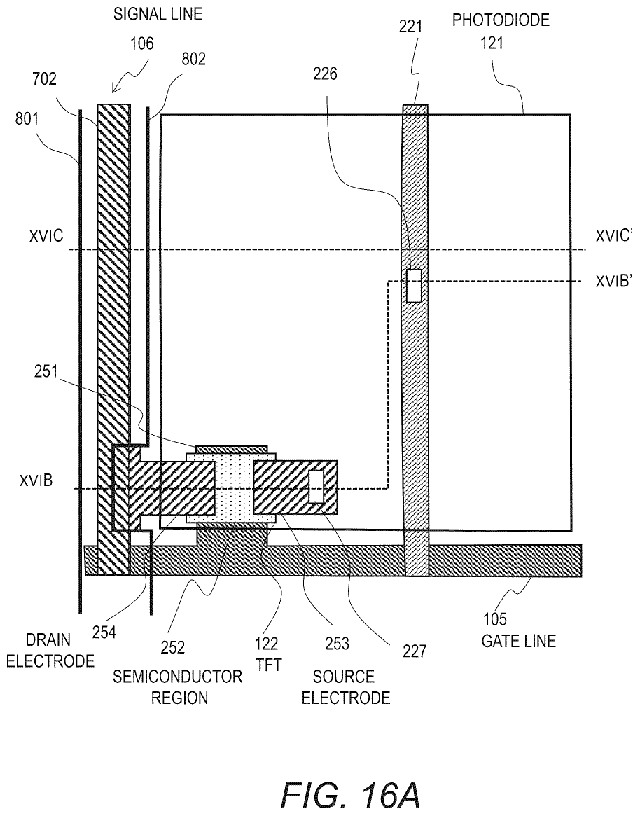

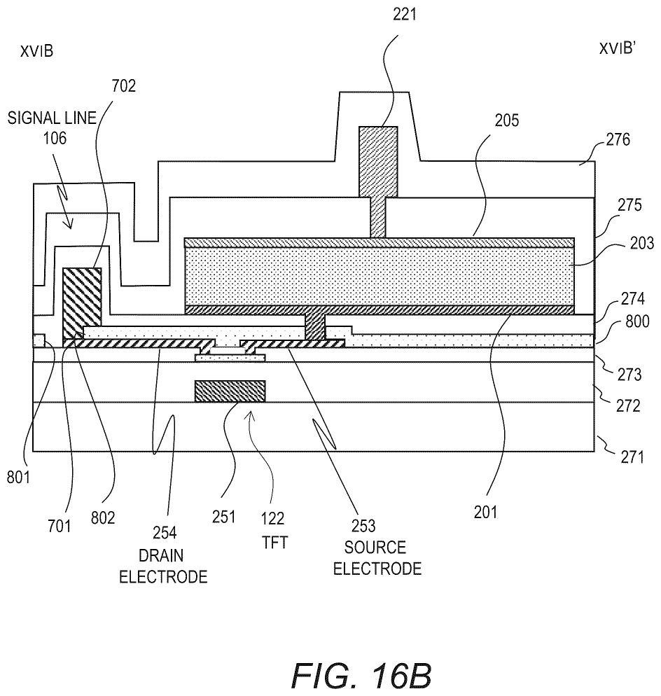

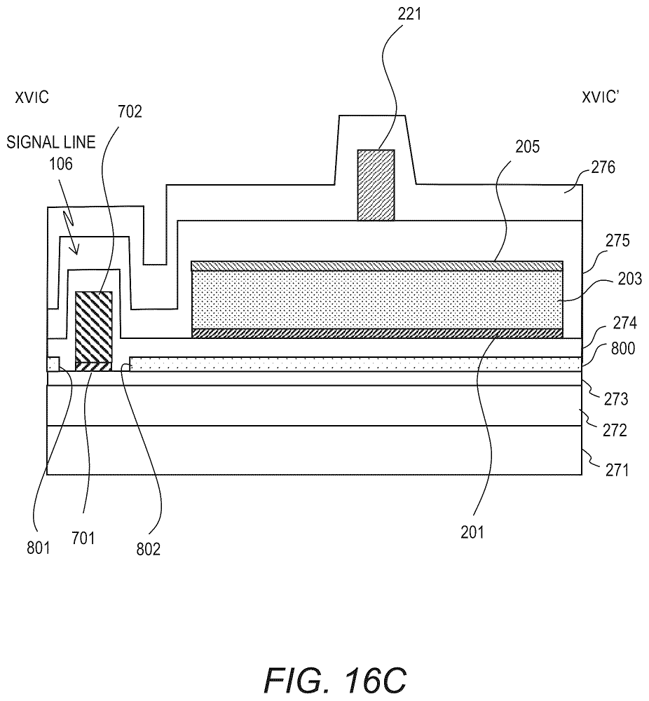

FIGS. 16A, 16B, and 16C illustrate the structure of a pixel 13 of an imaging element in an embodiment of this specification. FIG. 16B schematically illustrates the cross-sectional structure along the section line XVIB-XVIB′ in the plan diagram of FIG. 16A. FIG. 16C schematically illustrates the cross-sectional structure along the section line XVIC-XVIC′ in the plan diagram of FIG. 16A.

The insulating layer pattern 800 has edges 801 and 802. The region between the edges 801 and 802 is an opening region where the insulating layer pattern 800 does not exist and the region where the insulating film of the insulating layer patter 800 is removed. The most part of the signal line 106 is exposed in the opening region. The insulating layer pattern 800 covers the entire thin-film transistor 122 and parts of the gate line 105 and the signal line 106.

In a planar view, the insulating layer pattern 800 covers the entire region of the pixel 13 except for the part where an edge of the first metal layer pattern coincides with an edge of the second metal layer pattern and the neighboring region thereof. The first metal layer pattern includes the first signal line layer 701, the source electrode 253, and the drain electrode 254. The second metal layer pattern includes the second signal line layer 702.

With reference to FIG. 16B, the left edge of the first signal line layer 701 coincides with the left edge of the second signal line layer 702 in a planar view (when viewed in the layering direction). This part is located between the edges 801 and 802 of the insulating layer pattern 800 and is not covered with the insulating layer pattern 800. This part is the part where an edge of the first metal layer pattern coincides with an edge of the second metal layer pattern.

With reference to FIG. 16C, the left edge of the first signal line layer 701 coincides with the left edge of the second signal line layer 702 in a planar view (when viewed in the layering direction). The right edge of the first signal line layer 701 also coincides with the right edge of the second signal line layer 702 in a planar view (when viewed in the layering direction). These parts are located between the edges 801 and 802 of the insulating layer pattern 800 and are not covered with the insulating layer pattern 800. These parts are the parts where edges of the first metal layer pattern coincide with edges of the second metal layer pattern.

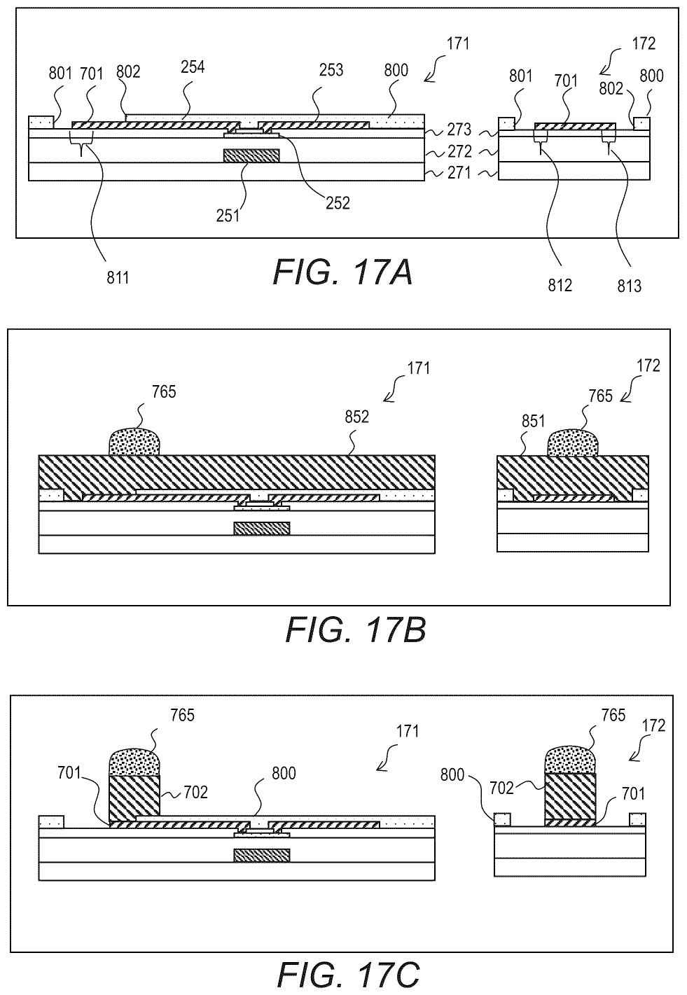

A manufacturing method of the structural example in FIGS. 16A, 16B, and 16C is described. FIGS. 17A, 17B, and 17C illustrate steps in the manufacturing method. The insulating films are produced by CVD and the metal films are produced by sputtering, for example. In FIGS. 17A, 17B, and 17C, the parts 171 illustrate the manufacturing steps of the thin-film transistor 122 and the signal line 106 shown in FIG. 16B and the parts 172 illustrate the manufacturing steps of the signal line 106 shown in FIG. 16C.

With reference to FIG. 17A, after producing a gate electrode 251, a gate insulating film 272, a semiconductor region 252, and a first interlayer insulating film 273 on a substrate 271, the method produces a first metal layer pattern. The first metal layer pattern includes a source electrode 253, drain electrode 254, a first signal line layer 701, and extensive regions 811, 812, and 813 of the first signal line layer 701. The source electrode 253 and the drain electrode 254 are in contact with the semiconductor region 252 via contact holes opened through the first interlayer insulating film 273.

Next, the method produces an insulating layer pattern 800. The insulating layer pattern 800 can be produced by depositing a silicon insulating film by CVD and etching the silicon insulating film using a photoresist. The opening region between the edges 801 and 802 of the insulating layer pattern 800 is a region where the insulating film is removed; the first signal line layer 701 and its extensive regions 811, 812, and 813 are not covered with the insulating film of the insulating layer pattern 800 and they are exposed from the insulating layer pattern 800.

Next, as illustrated in FIG. 17B, the method deposits a second metal film 852 covering the whole pixel region 12 (see FIG. 1) and deposits a resist film 765 on the top face of the second metal film 852. The resist film 765 covers the region corresponding to the second signal line layer 702.

Next, as illustrated in FIG. 17C, the method forms a metal layer pattern including the second signal line layer 702 by etching using the resist film 765. The insulating layer pattern 800 works as a mask for the source electrode 253 and the drain electrode 254. Specifically, the etching removes the extensive regions 811, 812, and 813, which are parts of the first metal layer pattern, and the second metal film 852 so that the left edge of the first signal line layer 701 coincides with the left edge of the second signal line layer 702.

Since the source electrode 253 and the drain electrode 254 in this embodiment are covered with the insulating layer pattern 800, this embodiment prevents undercuts in etching the second metal film 852 using the insulating films 731 and 732 as masks, compared to the embodiment illustrated in FIGS. 14A, 14B, 15A, 15B, and 15C. The undercuts are generated by excessively etching the second metal film 852 to form the edges of the source electrode 253 and the drain electrode 254 inner than the insulating films 731 and 732. The undercut diminishes the coatability of the second interlayer insulating film 274 to generate a void. The structure covered with the insulating layer pattern 800 prevents degradation in manufacturing quality such as disconnection, pattern breaking, and leak generated in the source electrode 253 and/or the drain electrode 254 because of permeation of etching solution caused by the undercut.

### Embodiment 5

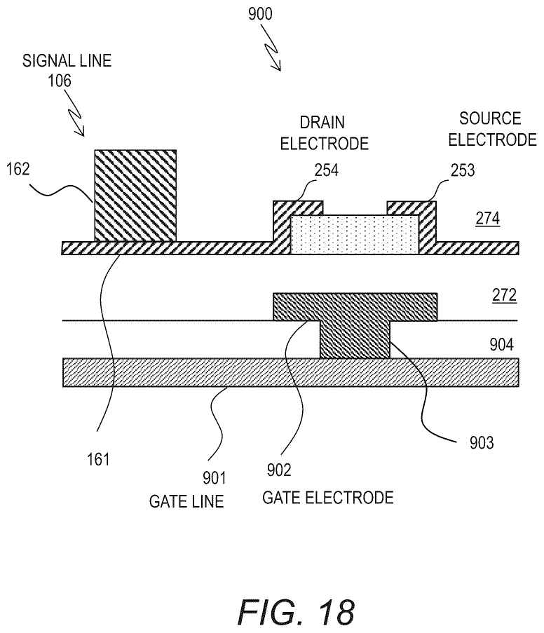

Hereinafter, some structural examples of a thin-film transistor or a photodiode are described. FIG. 18 is a cross-sectional diagram schematically illustrating a structural example of a thin-film transistor 900. The thin-film transistor 900 includes a gate line 901 and a gate electrode 902 in different metal layer patterns. In the structural examples described in the foregoing embodiments, the gate line and the gate electrode are included in the same metal layer pattern.

The gate electrode 902 located on an upper layer is connected to a gate line 901 on a lower layer via a contact region 903 extending through an insulating film 904 covering the gate line 901. The contact region 903 is included in the same metal layer pattern as the gate electrode 902. The gate line 901 and the gate electrode 902 can be made of the same or different metal materials. The structure upper than the gate electrode 902 is the same as the one in the structural example illustrated in FIG. 5A.

Providing the gate line on a layer different from the layer of the gate electrode, particularly a layer lower than the gate electrode, enables the gate electrode to be made thinner. Then, the height difference under the photodiode can be reduced and also, the parasitic capacitance between the gate line and the signal line can be reduced. This structure of the gate electrode and the gate line in the thin-film transistor 900 is applicable to the structures of the other thin-film transistors described in this specification.

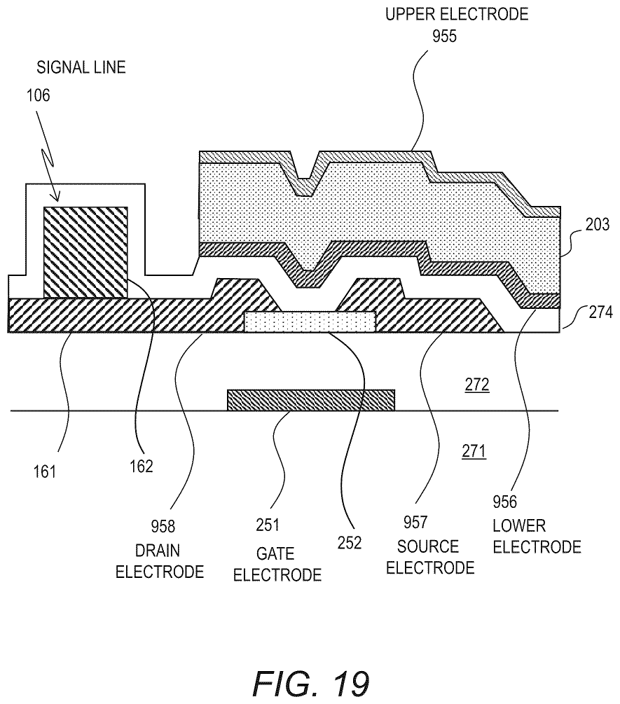

FIG. 19 is a cross-sectional diagram schematically illustrating a structural example of a thin-film transistor and a photodiode. Differences from the structural example in FIG. 3B are mainly described. The regions decreasing in height of the source electrode 957 and the drain electrode 958 are forward tapered. Each of the lower electrode 956 and the upper electrode 955 of the photodiode includes regions to be located over such regions of the source electrode 957 and the drain electrode 958. Since the source electrode 957 and the drain electrode 958 is forward tapered in the regions decreasing in height, the effect of these regions onto the characteristics of the photodiode can be reduced. This tapered shape is applicable to the other structures described in this specification with reference to the other drawings.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. An imaging element disposed on a substrate, the imaging element comprising:
a photodetector;
a thin-film transistor disposed between the photodetector and the substrate; and
a signal line configured to transmit a signal from the photodetector via the thin-film transistor,
wherein at least a part of the signal line includes a first signal line layer and a second signal line layer directly laid one above the other,
wherein at least a part of the thin-film transistor is covered with the photodetector in a planar view,
wherein the second signal line layer extends outside the photodetector in a planar view, and
wherein the first signal line layer is included in the same metal layer pattern as a drain electrode of the thin-film transistor and is continued to the drain electrode.

2. The imaging element according to claim 1, wherein the second signal line layer is thicker than the first signal line layer.

3. The imaging element according to claim 1, wherein the entire region of a source electrode of the thin-film transistor, the entire region of a semiconductor region of the thin-film transistor, and at least a part of the region of the drain electrode are covered with a light receiving region of the photodetector in a planar view.

4. The imaging element according to claim 1, wherein a first interlayer insulating film is interposed between a semiconductor region of the thin-film transistor and the drain electrode and a source electrode of the thin-film transistor.

5. The imaging element according to claim 1, wherein an edge of the signal line closer to a photodetector of an adjacent imaging element between edges defining a width of the signal line coincides with an edge of the second signal line layer in a planar view.

6. The imaging element according to claim 1,
wherein the second signal line layer is an upper layer and the first signal line layer is a lower layer in the signal line, and
wherein edges defining a width of the signal line coincide with edges of the second signal line layer in a planar view.

7. The imaging element according to claim 5,
wherein the second signal line layer is an upper layer and the first signal line layer is a lower layer in the signal line,
wherein the imaging element further comprises:
a first insulating film that is in direct contact with a top face of a source electrode of the thin-film transistor and covering the entire region of the source electrode except for a contact region to the photodetector; and
a second insulating film that is in direct contact with a top face of the drain electrode and covering the entire top face of the drain electrode, and
wherein a part of the second insulating film is only interposed in a part of a region between the first signal line layer and the second signal line layer and in direct contact with the first signal line layer and the second signal line layer.

8. The imaging element according to claim 5,
wherein the second signal line layer is an upper layer and the first signal line layer is a lower layer in the signal line,
wherein the first signal line layer and a source electrode of the thin-film transistor and the drain electrode are included in a first metal layer pattern,
wherein the second signal line layer is included in a second metal layer pattern,
wherein the imaging element further comprises an insulating layer pattern between the first metal layer pattern and the second metal layer pattern, and
wherein a part of the signal line where an edge of the first metal layer pattern coincides with an edge of the second metal layer pattern is located within an opening region of the insulating layer pattern in a planar view.

9. An image sensor comprising:
the substrate;
a plurality of the imaging elements according to claim 1 on the substrate;
a plurality of scanning lines on the substrate; and
a plurality of signal lines on the substrate.
